(19) United States
(12) Patent Application Publication
(10) Pub. No.: US 2025/0267968 A1
(43) Pub. Date: Aug. 21, 2025

(54) IMAGE SENSOR

(71) Applicant: Samsung Electronics Co., Ltd., Suwon-si (KR)

(72) Inventors: Dongmin KEUM, Suwon-si (KR); Duhyeon KWAK, Suwon-si (KR); Edwin KIM, Suwon-si (KR); Jinho KIM, Suwon-si (KR); Hyungeun YOO, Suwon-si (KR); Bumsuk KIM, Suwon-si (KR); Yun Ki LEE, Suwon-si (KR)

(73) Assignee: Samsung Electronics Co., Ltd., Suwon-si (KR)

(21) Appl. No.: 19/057,305

(22) Filed: Feb. 19, 2025

(30) Foreign Application Priority Data
Feb. 20, 2024 (KR) 10-2024-0024572

(51) Int. Cl. H10F 39/00

(52) U.S. Cl. CPC H10F 39/8053; H10F 39/8063; H10F 39/807

(57) ABSTRACT

An image sensor that includes a substrate including a pixel array area and a dummy pixel area surrounding the pixel array area; a plurality of photodiodes within the substrate; a pixel separation pattern between the plurality of photodiodes; a light blocking pattern overlapping at least one of the plurality of photodiodes in the dummy pixel area; a plurality of color filters on the plurality of photodiodes; and a microlens layer on the plurality of color filters and the light blocking pattern, the microlens layer including a flat portion and a plurality of microlenses. In the dummy pixel area the flat portion of the microlens layer overlaps the light blocking pattern, the plurality of microlenses are spaced apart with the flat portion interposed between microlenses of the plurality of microlenses, and the microlenses are on the plurality of color filters.

### CROSS-REFERENCE TO RELATED APPLICATION

This application claims priority to and the benefit of Korean Patent Application No. 10-2024-0024572 filed in the Korean Intellectual Property Office on Feb. 20, 2024, the entire contents of which is incorporated herein by reference.

### BACKGROUND

The present disclosure relates to image sensors.

A CMOS image sensor is a solid-state imaging device using complementary metal-oxide semiconductor (CMOS). Compared to CCD image sensors with high-voltage analog circuits, CMOS image sensors have the advantage of low manufacturing cost and low power consumption due to small device size, and therefore, CMOS image sensors are mainly used in home appliances including portable devices such as smartphones and digital cameras.

The pixel array that makes up a CMOS image sensor includes a photodiode for each pixel. The photodiode generates an electrical signal that varies depending on the amount of incident light, and the CMOS image sensor processes the electrical signal to synthesize an image.

Recently, in response to the demand for high-resolution images, the pixels that make up CMOS image sensors are required to be smaller. As the demand for miniaturization increases, incident light may not be sensed properly or noise may occur due to interference between devices with increased integration.

Despite the miniaturization of CMOS image sensors, demands for improved image quality and performance of additional functions are increasing, and therefore, various research is being conducted to accurately determine the location of defective pixels in order to improve the reliability and productivity of CMOS image sensors.

### SUMMARY

Some example embodiments of the present disclosure provide an image sensor having improved reliability and productivity.

Some example embodiments provide an image sensor that includes a substrate including a pixel array area and a dummy pixel area surrounding the pixel array area; a plurality of photodiodes within the substrate; a pixel separation pattern between the plurality of photodiodes; a light blocking pattern overlapping at least one of the plurality of photodiodes in the dummy pixel area; a plurality of color filters on the plurality of photodiodes; and a microlens layer on the plurality of color filters and the light blocking pattern, the microlens layer including a flat portion and a plurality of microlenses. In the dummy pixel area the flat portion of the microlens layer overlaps the light blocking pattern, the plurality of microlenses of the microlens layer are spaced apart with the flat portion interposed between microlenses of the plurality of microlenses, and the plurality of microlenses are located on the plurality of color filters.

Some example embodiments further provide an image sensor that includes a substrate including a pixel array area and a dummy pixel area surrounding the pixel array area; a plurality of photodiodes within the substrate; a pixel separation pattern between the plurality of photodiodes; a light blocking pattern overlapping at least one of the plurality of photodiodes in the dummy pixel area; a plurality of color filters on the plurality of photodiodes; a grid pattern between the plurality of color filters, the grid pattern overlapping the pixel separation pattern; and a microlens layer including a flat portion and a plurality of microlenses, the microlens layer being on the plurality of color filters and the light blocking pattern. In the dummy pixel area the plurality of color filters cover at least a portion of an upper surface of the light blocking pattern, the flat portion overlaps the light blocking pattern, the plurality of microlenses are spaced apart with the flat portion interposed between microlenses of the plurality of microlenses, and the plurality of microlenses are on the plurality of color filters.

Some example embodiments still further provide an image sensor that includes a substrate including a pixel array area and a dummy pixel area surrounding the pixel array area; a plurality of photodiodes within the substrate; a pixel separation pattern between the plurality of photodiodes; a light blocking pattern overlapping at least one of the plurality of photodiodes in the dummy pixel area; a plurality of color filters on the plurality of photodiodes and the light blocking pattern; a grid pattern between the plurality of color filters, the grid pattern overlapping the pixel separation pattern; and a plurality of microlenses on the plurality of color filters. In the dummy pixel area the light blocking pattern is entirely covered by the plurality of color filters, and the light blocking pattern overlaps the plurality of microlenses.

According to some example embodiments, by forming a mark pattern overlapping at least one of photodiodes located corresponding to a plurality of dummy pixels located in the dummy pixel area whereby the mark pattern functions as a light blocking pattern that is not covered by a color filter and microlenses, visibility with respect to the mark pattern when viewing the dummy pixel area and on an output image may be improved.

Accordingly, the location of the defective pixel included in the pixel array area may be clearly identified.

### BRIEF DESCRIPTION OF THE DRAWINGS

FIG. 1 is a block diagram of an image sensor according to some example embodiments of the present disclosure.

FIG. 2 is a top plan view of an image sensor according to some example embodiments.

FIG. 3 is a partial enlarged view of region P1 of FIG. 2.

FIG. 4 is a partial enlarged view of region P2 of FIG. 3.

FIG. 5 is a partial enlarged view of region P3 of FIG. 3.

FIG. 6 shows cross-sectional views taken along lines I-I′ and II-II′ of FIG. 4.

FIG. 7 is an enlarged cross-sectional view of a region corresponding to line II-II′ of FIG. 6.

FIGS. 8, 9, 10, 11, 12 and 13 are cross-sectional views taken along line II-II′ of FIG. 4 according to some example embodiments.

FIG. 14 is a plan view showing a pixel array area and dummy pixel area of image sensors according to some example embodiments.

FIG. 15 is a cross-sectional view taken along line III-III′ of FIG. 14.

FIG. 16 is a plan view showing a pixel array area and dummy pixel area of image sensors according to some example embodiments.

FIG. 17 is a cross-sectional view taken along line IV-IV′ of FIG. 16.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

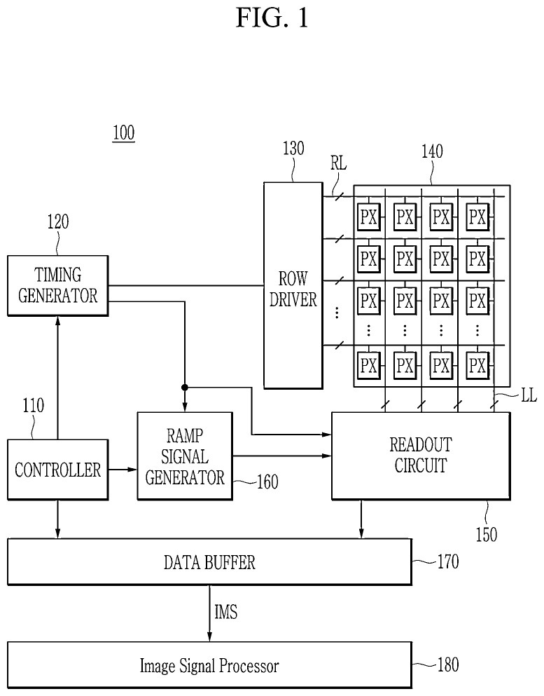

Hereinafter, referring to FIG. 1 to FIG. 7, an image sensor according to some example embodiments will be described.

FIG. 1 is a block diagram of an image sensor according to some example embodiments.

Referring to FIG. 1, an image sensor 100 according to some example embodiments may include a controller 110, a timing generator 120, a row driver 130, a pixel array 140, a readout circuit 150, a ramp signal generator 160, data buffer 170 and an image signal processor 180. In some example embodiments, the image signal processor 180 may be located outside image sensor 100.

The image sensor 100 may convert the light received from the outside to an electric signal to generate the image signal. An image signal IMS may be provided to the image signal processor 180.

The image sensor 100 may be installed in an electronic device having an image or light sensing function. For example, the image sensor 100 may be installed in electronic devices such as a camera, a smart phone, a wearable device, an Internet of Things (IoT) device, a home appliance, a tablet PC (personal computer), a personal digital assistant (PDA), a portable multimedia player (PMP), a navigation, a drone, an advanced drivers assistance system (ADAS). Alternatively, the image sensor 100 may be mounted on an electronic device that is provided as a part of a vehicle, furniture, manufacturing facility, door, or various measuring devices.

The controller 110 may generally control respective components 120, 130, 150, 160, and 170 included in the image sensor 100. The controller 110 may control respective operation timings of the components 120, 130, 150, 160, and 170 by using control signals. In some example embodiments, the controller 110 may receive a mode signal indicating an imaging mode from an application processor, and may generally control the image sensor 100 based on the received mode signal. For example, the application processor may determine the imaging mode of the image sensor 100 according to various scenarios such as the illumination of the imaging environment, the user's resolution setting, the sensed or learned state, or the like, and provide the determined result to the controller 110 by the mode signal. The controller 110 may control a plurality of pixels of the pixel array 140 to output a pixel signal according to the imaging mode, the pixel array 140 may output a pixel signal with respect to each of the plurality of pixels or a pixel signal with respect to a portion of the plurality of pixels, and the readout circuit 150 may sample and process the pixel signals transferred from the pixel array 140. The timing generator 120 may generate a signal that may become a reference of operation timing of configurations of the image sensor 100. The timing generator 120 may control the timing of the row driver 130, the readout circuit 150, and the ramp signal generator 160. The timing generator 120 may provide a control signal that controls the timing of the row driver 130, the readout circuit 150 and the ramp signal generator 160.

The pixel array 140 may include a plurality of active pixels PX, and a plurality of row lines RL and a plurality of column lines LL connected to the plurality of active pixels PX, respectively. In some example embodiments, each active pixel PX may include at least one photoelectric conversion device. The photoelectric conversion device may detect incident light, and may convert incident light to an electric signal according to the amount of light, e.g., a plurality of analog pixel signals. The photoelectric conversion device may be a photodiode, a pinned diode, or the like.

The photoelectric conversion device may be a single-photon avalanche diode (SPAD) applied to a 3D sensor pixel. A level of the analog pixel signals output from the photoelectric conversion device may be proportional to an amount of charges output from the photoelectric conversion device. That is, the level of the analog pixel signals output from the photoelectric conversion device may be determined according to the amount of light received into the pixel array 140.

The plurality of row lines RL may extend in a first direction, and may be connected to the active pixels PX disposed along the first direction. For example, the control signal output from the row driver 130 to the row line RL may be transferred to a gate of a transistor of the plurality of active pixels PX connected to the corresponding row line RL. The column line LL may extend in a second direction crossing the first direction, and may be connected to the plurality of active pixels PX disposed along the second direction. The plurality of pixels signal output from the plurality of active pixels PX may be transferred to the readout circuit 150 through the plurality of column lines LL.

A color filter layer and a microlens layer may be located on the pixel array 140. The microlens layer may include a plurality of microlenses, and at least one active pixel PX corresponding to each of the plurality of microlenses may be located therein.

The color filter layer may include color filters of red, green, and blue, or the like, and may further include a white filter. With respect to one active pixel PX, a color filter of one color may be located between microlenses corresponding to the active pixel PX.

The row driver 130 may generate a control signal for driving the pixel array 140 in response to a control signal of the timing generator 120, and may provide the control signal to the plurality of active pixels PX of the pixel array 140 through the plurality of row lines RL.

In some example embodiments, the row driver 130 may control the active pixel PX to detect incident light in the unit of row lines. The row line unit may include at least one row line RL. For example, the row driver 130 may provide a transmission signal, a reset signal, a selection signal, or the like to the pixel array 140.

The readout circuit 150 may convert the pixel signal (or electric signal) from the active pixels PX connected to the row line RL selected from among the plurality of active pixels PX to a pixel value representing the amount of light in response to control signal from the timing generator 120. The readout circuit 150 may convert the pixel signal output through the corresponding column line LL to the pixel value. For example, the readout circuit 150 may compare a ramp signal and the pixel signal, and thereby convert the pixel signal to the pixel value. The pixel value may be an image data having a plurality of bits. For example, the readout circuit 150 may include a selector, a plurality of comparators, and a plurality of counter circuits, or the like.

The ramp signal generator 160 may generate a reference signal, and may transmit it to the readout circuit 150.

The ramp signal generator 160 may include a current source, a resistor, and a capacitor. The ramp signal generator 160 may adjust a ramp voltage, which is a voltage applied to the ramp resistance by adjusting a current size of a variable current source or a resistance value of a variable resistor, and thereby may generate a plurality of ramp signals rising or falling in a slope determined according to the current size of the variable current source or the resistance value of the variable resistor.

The data buffer 170 may store the pixel value of the plurality of active pixels PX connected to the selected column line LL transferred from the readout circuit 150, and output the stored pixel value in response to enable signal from the controller 110.

The image signal processor 180 may perform image signal processing on the image signal received from the data buffer 170. For example, the image signal processor 180 may receive a plurality of image signals from the data buffer 170, and generate one image by synthesizing the received image signal.

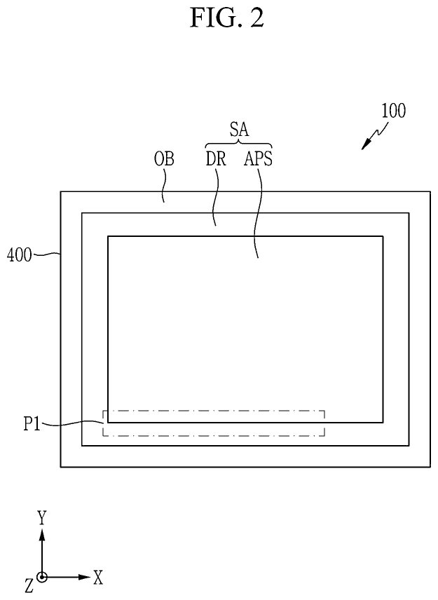

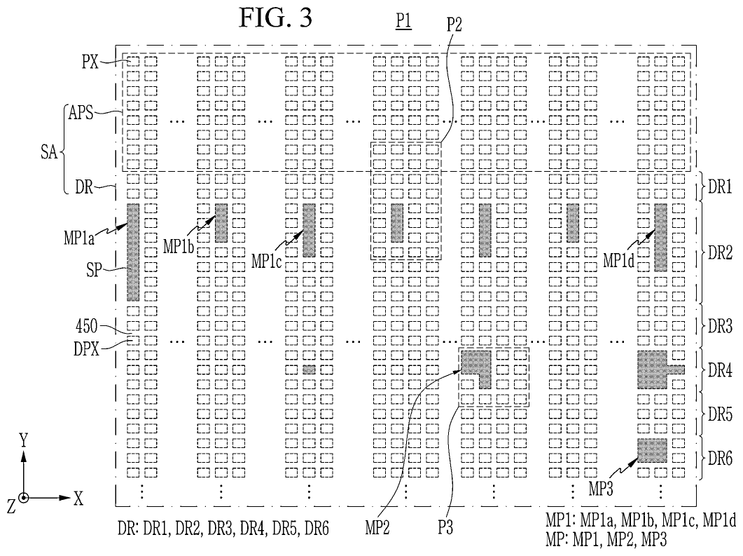

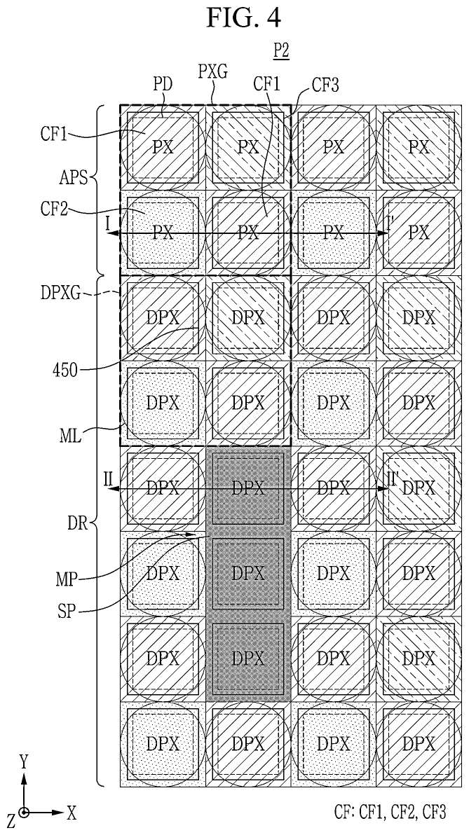

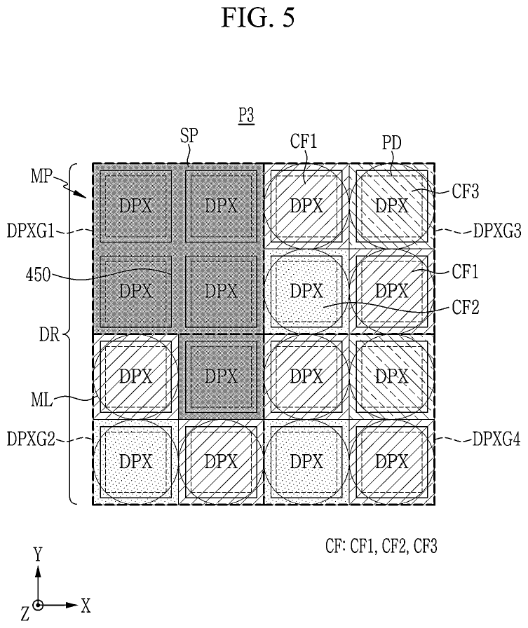

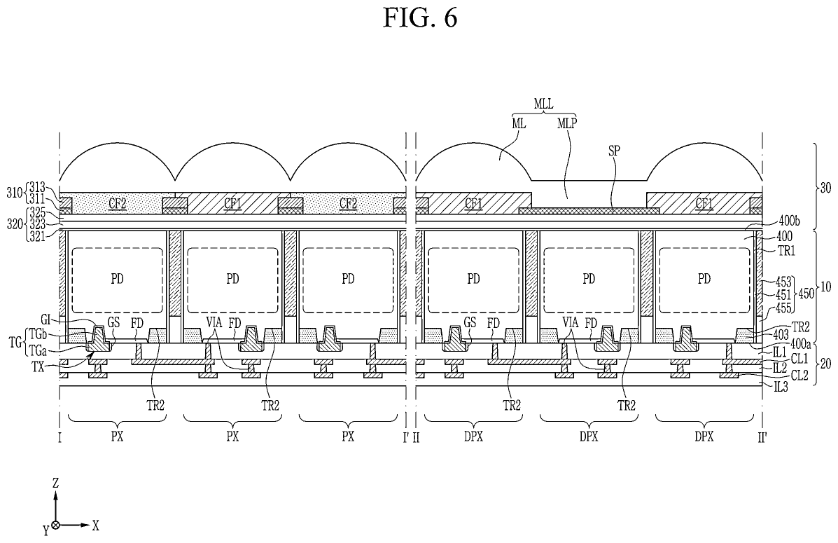

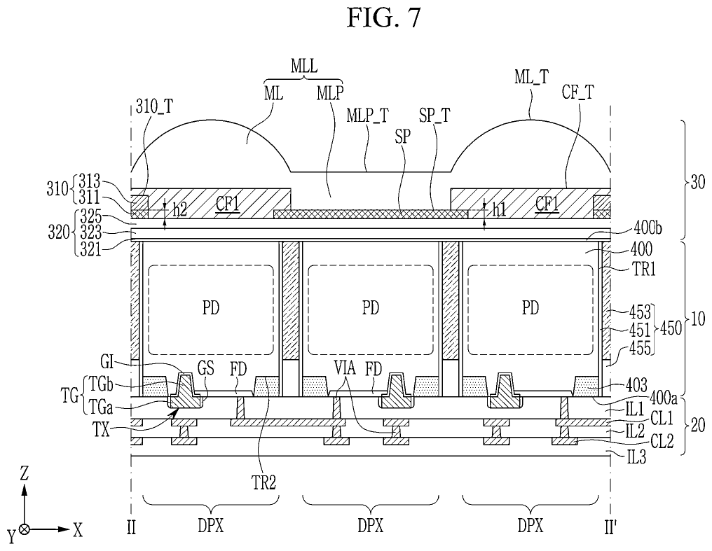

FIG. 2 is a top plan view of an image sensor according to some example embodiments. FIG. 3 is a partial enlarged view of a region P1 of FIG. 2. FIG. 4 is a partial enlarged view of a region P2 of FIG. 3. FIG. 5 is a partial enlarged view of a region P3 of FIG. 3. FIG. 6 is a cross-sectional view taken along lines I-I′ and II-II′ of FIG. 4. FIG. 7 is an enlarged cross-sectional view of a region correspond to line II-II′ of FIG. 6.

Referring to FIG. 2 to FIG. 7, the image sensor 100 according to some example embodiments may include a photoelectric conversion layer 10, a wire region 20, and a light transmitting layer 30. The photoelectric conversion layer 10 may be located between the wire region 20 and the light transmitting layer 30. That is, the wire region 20, the photoelectric conversion layer 10, and the light transmitting layer 30 may be sequentially located along a third direction Z, which is a vertical direction.

The photoelectric conversion layer 10 may include a substrate 400, photodiodes PD located within the substrate 400, and a pixel separation pattern 450 located between the photodiodes PD. A light incident from the outside may be converted to electrical signals by each of the photodiodes PD.

In some example embodiments, the substrate 400 may include a sensor array area SA and an optical black area OB. The sensor array area SA may be surrounded by the optical black area OB, in a plan view. Although not shown in FIG. 2, in some example embodiments, the substrate 400 may be located in an outer side of the optical black area OB, and may further include a pad region (not shown) where a pad configured to output the signal generated by the sensor array area SA to the outside, or transfer an external electrical signal or voltage to the sensor array area SA is located.

The sensor array area SA may include a pixel array area APS and a dummy pixel area DR.

The pixel array area APS may be located in approximately a center area of the substrate 400. The dummy pixel area DR may be located in an outer side of the pixel array area APS in the first direction X and an outer side of the second direction Y. That is, the dummy pixel area DR may extend along an outer circumference of the pixel array area APS in a plan view, and may entirely surround the pixel array area APS. The dummy pixel area DR may be located between the pixel array area APS and the optical black area OB.

Although it is illustrated in FIG. 2 that the dummy pixel area DR is located according to all four edges of the pixel array area APS, arrangement relationship between the pixel array area APS and the dummy pixel area DR is not limited thereto, and may be changed in various ways. For example, the dummy pixel area DR may be located along a partial region of the edge of the pixel array area APS.

In some example embodiments, an area of the pixel array area APS in a plan view and an area of the dummy pixel area DR in a plan view be different. For example, the area of the pixel array area APS in a plan view may be greater than the area of the dummy pixel area DR in a plan view. However, relationship between the area of the pixel array area APS in a plan view and the area of the dummy pixel area DR in a plan view is not limited thereto, and may be changed in various ways.

The active pixels PX may be located in the pixel array area APS, and dummy pixels DPX may be located in the dummy pixel area DR.

In each of the pixel array area APS and the dummy pixel area DR, the active pixels PX and the dummy pixels DPX may be located along the first direction X and the second direction Y. That is, the active pixels PX and the dummy pixels DPX may be arranged in a matrix shape along rows parallel to the first direction X and columns parallel to the second direction Y, in a plan view.

The active pixels PX and the dummy pixels DPX may output a photoelectric signal from the incident light. However, in some example embodiments, the dummy pixels DPX have substantially the same or similar structure as the active pixel PX, and may not perform the same operation (e.g., an operation of outputting a photoelectric signal from the incident light) as the active pixels PX.

As shown in FIG. 3, in some example embodiments, a plurality of mark patterns MP for specifying a location of a defective pixel among the active pixels PX located in the pixel array area APS may be located in the dummy pixel area DR located on a first side of the pixel array area APS in the second direction Y. The mark pattern MP located in the dummy pixel area DR may have various shapes in a plan view, and may specify the location of the defective pixel located in the pixel array area APS according to a shape of the mark pattern MP.

The mark pattern MP located in the dummy pixel area DR may be configured as a light blocking pattern SP located to overlap with at least one of a plurality of dummy pixels DPX. The light blocking pattern SP may overlap with one dummy pixel DPX or the plurality of dummy pixels DPX. The shape of the mark pattern MP in a plan view may be changed in various ways according to an arrangement form in a plan view of the light blocking pattern SP overlapping with the dummy pixel DPX.

The dummy pixel area DR located on the first side of the pixel array area APS may include a first dummy pixel area DR1, a second dummy pixel area DR2, a third dummy pixel area DR3, a fourth dummy pixel area DR4, a fifth dummy pixel area DR5, and a sixth dummy pixel area DR6 that are sequentially located along the second direction Y.

The dummy pixels DPX and the pixel separation pattern 450 located therebetween may be located in each of the first to sixth dummy pixel areas DR1, DR2, DR3, DR4, DR5, and DR6. In FIG. 3, the number and arrangement of the dummy pixel DPX included each of the first to sixth dummy pixel areas DR1, DR2, DR3, DR4, DR5, and DR6 is merely an example, to be not limited thereto, and may be changed in various ways.

In some example embodiments, a first mark pattern MP1, a second mark pattern MP2, and a third mark pattern MP3 may be located in each of the second dummy pixel area DR2, the fourth dummy pixel area DR4, and the sixth dummy pixel area DR6, while not being located in the first dummy pixel area DR1, the third dummy pixel area DR3, the fifth dummy pixel area DR5.

In the dummy pixel area DR, each of the first dummy pixel area DR1, the third dummy pixel area DR3, the fifth dummy pixel area DR5 may perform the function of a boundary to distinguish the second dummy pixel area DR2, the fourth dummy pixel area DR4, and the sixth dummy pixel area DR6. However, an arrangement form of the mark pattern MP is not limited thereto, and may be changed in various ways.

The mark patterns MP located in the dummy pixel area DR may represent a X-coordinate value for specifying a location of the active pixels PX located in the pixel array area APS. That is, the X-coordinate of the active pixel PX located in the pixel array area APS may be specified by a combination of the first mark pattern MP1, the second mark pattern MP2 and the third mark pattern MP3.

In more detail, the first mark pattern MP1 located in the second dummy pixel area DR2 may extend along the second direction Y, and may have a line shape, in a plan view. That is, the light blocking pattern SP constituting the first mark patterns MP1 may extend to overlap with the plurality of dummy pixels DPX arranged side by side along the second direction Y in the second dummy pixel area DR2.

The light blocking pattern SP constituting the first mark pattern MP1 may extend along the second direction Y to overlap with the plurality of dummy pixels DPX, and may overlap with the pixel separation pattern 450 located between the dummy pixels DPX.

The first mark pattern MP1 located in the second dummy pixel area DR2 may include a first sub-mark pattern MP1a, a second sub-mark pattern MP1b, a third sub-mark pattern MP1c, and a fourth sub-mark pattern MP1d having different lengths along the second direction Y.

The first sub-mark pattern MP1a configured as the light blocking pattern SP overlapping with the dummy pixels DPX arranged in substantially the same row as the active pixels PX located outermost of the pixel array area APS among the first mark pattern MP1 located in the second dummy pixel area DR2 may mean an origin or starting point of the X-coordinate value for representing the location of the active pixels PX located in the pixel array area APS.

Lengths along the second direction Y of the second sub-mark pattern MP1b, the third sub-mark pattern MP1c, and the fourth sub-mark pattern MP1d among the first mark pattern MP1 located in the second dummy pixel area DR2 may be different.

The length of the second sub-mark pattern MP1b along the second direction Y may be the shortest, a length of the third sub-mark pattern MP1c along the second direction Y may be longer than the length of the second sub-mark pattern MP1b along the second direction Y and shorter than a length of the fourth sub-mark pattern MP1d along the second direction Y, and the length of the fourth sub-mark pattern MP1d along the second direction Y may be the longest.

In some example embodiments, each of the lengths of the second sub-mark pattern MP1b, the third sub-mark pattern MP1c, and the fourth sub-mark pattern MP1d along the second direction Y may sequentially increase. For example, a difference between the length of the second sub-mark pattern MP1b and the length of the third sub-mark pattern MP1c along the second direction Y may be substantially the same as a difference between the length of the third sub-mark pattern MP1c and the length of the fourth sub-mark pattern MP1d along the second direction Y.

That is, the second sub-mark pattern MP1b may be configured as the light blocking pattern SP extending to overlap with three dummy pixels DPX in the second dummy pixel area DR2, the third sub-mark pattern MP1c may be configured as the light blocking pattern SP extending to overlap with four dummy pixels DPX in the second dummy pixel area DR2, and the fourth sub-mark pattern MP1d may be configured as the light blocking pattern SP extending to overlap with five dummy pixels DPX in the second dummy pixel area DR2. However, the number of the dummy pixels DPX overlapped by the light blocking pattern SP constituting each of the second sub-mark pattern MP1b, the third sub-mark pattern MP1c, and the fourth sub-mark pattern MP1d is not limited thereto, and may be changed in various ways.

In more detail, the first sub-mark pattern MP1a may have the longest length along the second direction Y, among a plurality of first mark patterns MP1 located in the second dummy pixel area DR2. For example, the first sub-mark pattern MP1a may be configured as the light blocking pattern SP overlapping with seven dummy pixels DPX arranged side by side along the second direction Y in the second dummy pixel area DR2.

The second sub-mark patterns MP1b having a shortest length along the second direction Y among the first mark pattern MP1 located in the second dummy pixel area DR2 may mean the X-coordinate value in the unit of 10 of the active pixels PX located in the pixel array area APS. That is, the second sub-mark patterns MP1b may be repeatedly located in the unit of 10 from the first sub-mark pattern MP1a that means an origin of the X-coordinate value of the active pixels PX located in the pixel array area APS.

The third sub-mark patterns MP1c whose length along the second direction Y is secondarily short among the first mark pattern MP1 located in the second dummy pixel area DR2 may mean the X-coordinate value in the unit of 100 of the active pixels PX located in the pixel array area APS. That is, the third sub-mark patterns MP1c may be repeatedly located in the unit of 100 from the first sub-mark pattern MP1a that means the origin of the X-coordinate value of the active pixels PX located in the pixel array area APS.

The fourth sub-mark patterns MP1d whose length along the second direction Y is thirdly short among the first mark pattern MP1 located in the second dummy pixel area DR2 may mean the X-coordinate value in the unit of 1000 of the active pixels PX located in the pixel array area APS. That is, the fourth sub-mark patterns MP1d may be repeatedly located in the unit of 1000 from the first sub-mark pattern MP1a that means the origin of the X-coordinate value of the active pixels PX located in the pixel array area APS. However, the number of the dummy pixels DPX overlapping with the light blocking pattern SP constituting the first mark pattern MP1 is merely an example, being not limited thereto, and may be changed in various ways.

The second mark pattern MP2 and the third mark pattern MP3 located in each of the fourth dummy pixel area DR4 and the sixth dummy pixel area DR6 may overlap with at least one dummy pixel DPX, and may have an island shape, in a plan view. That is, the light blocking pattern SP constituting each of the second mark patterns MP2 and the third mark patterns MP3 may overlap with one or more dummy pixels DPX among the dummy pixels DPX arranged along the first direction X and the second direction Y, and in a plan view, may have an island shape. Here, island shape is not limited to a quadrangle shape in a plan view, and may be changed in various ways according to the arrangement form of the light blocking pattern SP.

The light blocking pattern SP constituting the second mark pattern MP2 and the third mark pattern MP3 may extend along the first direction X and/or extend along the second direction Y to overlap with the plurality of dummy pixels DPX, and may overlap with the pixel separation pattern 450 located between the dummy pixels DPX.

The second mark pattern MP2 located in the fourth dummy pixel area DR4 may mean the X-coordinate value for the digit of 100 of the active pixels PX located in the pixel array area APS. That is, the X-coordinate value for the digit of 100, between 100 to 900, of the active pixels PX located in the pixel array area APS may be specified by combining the third sub-mark pattern MP1c meaning the X-coordinate value in the unit of 100 of the active pixels PX located in the pixel array area APS among the first mark pattern MP1 located in the second dummy pixel area DR2 and the second mark pattern MP2 located in the fourth dummy pixel area DR4.

That is, the X-coordinate value for the digit of 100 may be specified by the number by which the second mark pattern MP2 and the dummy pixels DPX arranged in a 3×3 matrix shape in a plan view around the dummy pixel DPX located in substantially the same row as the third sub-mark pattern MP1c in the fourth dummy pixel area DR4 overlap with each other.

For example, as shown in FIG. 3, when the second mark pattern MP2 overlaps with one dummy pixel DPX in the fourth dummy pixel area DR4, the X-coordinate value of the active pixels PX located in the pixel array area APS may mean 100, and when the second mark pattern MP2 overlaps with the five dummy pixel DPX in the fourth dummy pixel area DR4, the X-coordinate value of the active pixels PX located in the pixel array area APS may mean 500, and when the second mark pattern MP2 overlaps with the seven dummy pixel DPX in the fourth dummy pixel area DR4, the X-coordinate value of the active pixels PX located in the pixel array area APS may mean 700. However, this is merely an example, and an arrangement form of the second mark pattern MP2 in a plan view and a coordinate value according thereto may be changed in various ways.

After specifying the X-coordinate value for the digit of 100, between 100 to 900, of the active pixels PX located in the pixel array area APS by combining the second mark pattern MP2 and the third sub-mark pattern MP1c among the first mark pattern MP1, the X-coordinate value for the digit of 10, between 100 to 900 may be specified by using the second sub-mark pattern MP1b among the first mark pattern MP1, as described above.

Although FIG. 3 does not illustrate the mark pattern MP for specifying the X-coordinate value for the digit of 1, in some example embodiments, the mark pattern MP located in the dummy pixel area DR may further include a mark pattern for specifying the X-coordinate value for the digit of 1 of the active pixels PX located in the pixel array area APS.

The third mark pattern MP3 located in the sixth dummy pixel area DR6 may mean the X-coordinate value for the digit of 1000 of the active pixels PX located in the pixel array area APS. That is, the X-coordinate value for the digit of 1000, between 1000 to 9000 may be specified by combining the fourth sub-mark pattern MP1d meaning the X-coordinate value in the unit of 1000 of the active pixels PX located in the pixel array area APS among the first mark pattern MP1 located in the second dummy pixel area DR2 and the third mark pattern MP3 located in the sixth dummy pixel area DR6.

That is, the X-coordinate value for the digit of 1000 may be specified by the number by which pixels DPX and the third mark pattern MP3 arranged in a 3×3 matrix shape in a plan view around the dummy pixel DPX located in substantially the same row as the fourth sub-mark pattern MP1d in the sixth dummy pixel area DR6 overlap with each other.

For example, as shown in FIG. 3, when the third mark pattern MP3 overlaps with the four dummy pixel DPX in the sixth dummy pixel area DR6, the X-coordinate value of the active pixels PX located in the pixel array area APS may mean 4000. However, this is merely an example, and an arrangement form of the third mark pattern MP3 in a plan view and a coordinate value according thereto may be changed in various ways.

After specifying the X-coordinate value for the digit of 1000, between 1000 to 9000, of the active pixels PX located in the pixel array area APS by combining the third mark pattern MP3 and the fourth sub-mark pattern MP1d among the first mark pattern MP1, the X-coordinate value for the digit of 100, between 100 to 900 may be specify by using the third sub-mark pattern MP1c among the first mark pattern MP1, as described above.

For example, as described above, when the fourth sub-mark pattern MP1d located in the second dummy pixel area DR2, the second mark pattern MP2 located in the fourth dummy pixel area DR4 and overlapping with the seven dummy pixels DPX, and the third mark pattern MP3 located in the sixth dummy pixel area DR6 and overlapping with the four dummy pixels DPX are combined, the X-coordinate value of the active pixels PX located in the pixel array area APS may mean 4700.

Although not shown in FIG. 3, in some example embodiments, the first mark pattern MP1 may further include a mark pattern other than the first to fourth sub-mark patterns MP1a, MP1b, MP1c, and MP1d.

For example, the first mark pattern MP1 may have a length along the second direction Y longer than the length of the fourth sub-mark pattern MP1d along the second direction Y, and may be located in the second dummy pixel area DR2 to further include a mark pattern meaning the X-coordinate value in the unit of 10000 of the active pixels PX located in the pixel array area APS.

Although FIG. 3 provides illustration and explanation focusing on the mark pattern MP located in the dummy pixel area DR located on a first side of the second direction Y of the pixel array area APS, the mark pattern MP described above may be located in at least one of the dummy pixel areas DR located on a first side and a second side of the pixel array area APS in the first direction X, to represent the Y-coordinate value for specifying the location of the active pixels PX.

That is, the first mark pattern MP1, the second mark pattern MP2 and the third mark pattern MP3 described above may be located in a first one of the dummy pixel areas DR located on the first side and the second side of the pixel array area APS in the first direction X, and the Y-coordinate of the active pixel PX located in the pixel array area APS may be specified by a combination of the first mark pattern MP1, the second mark pattern MP2 and the third mark pattern MP3. Accordingly, the X-coordinate and Y-coordinate of the active pixels PX located in the pixel array area APS may be specified.

Although FIG. 3 provides illustration and explanation focusing on the mark pattern MP located in the dummy pixel area DR located on a first side of the second direction Y of the pixel array area APS, a location of the mark pattern MP is not limited thereto, and in some example embodiments, the mark pattern MP described above may be located in at least one of the dummy pixel areas DR located on a first side and a second side of the pixel array area APS in the second direction Y.

The optical black area OB may be located in an outer side of the dummy pixel area DR in the first direction X and the outer side of the second direction Y. That is, the optical black area OB may extend along an outer circumference of the dummy pixel area DR in a plan view, and may entirely surround the dummy pixel area DR.

Pixels located in the optical black area OB may be covered by a light blocking layer (not shown). That is, the light incident on the pixels located in the optical black area OB may be blocked by a light blocking layer.

The pixels located in the optical black area OB may function as a reference pixel with respect to the active pixels PX located in the pixel array area APS, and may perform the function for automatically compensating dark signals. That is, a reference charge amount that may be generated within the reference pixel to which the light is blocked is measured, this is compared with a sensing charge amount generated from the active pixel PX, the light signal input from the pixel array area APS may be calculated from a difference between the sensing charge amount and the reference charge amount, and may be used as information for removing process noises.

The substrate 400 may include a first surface 400a and a second surface 400b facing each other in the third direction Z, which is the vertical direction. The second surface 400b of the substrate 400 may be a light receiving surface on which the light is incident.

A first wire region 20 may be located on the first surface 400a of the substrate 400, and the light transmitting layer 30 may be located on the second surface 400b of a first substrate 400. That is, the substrate 400 may be located between the wire region 20 and the light transmitting layer 30.

The substrate 400 may be a semiconductor substrate or a silicon-on-Insulator (SOI) substrate. The semiconductor substrate may include, for example, a silicon substrate, a germanium substrate, or a silicon-germanium substrate. The substrate 400 may include impurities of a first conductivity type. For example, impurities of the first conductivity type may be P-type impurities such as aluminum (Al), boron (B), indium (In) and/or gallium (Ga).

The substrate 400 may include the plurality of active pixels PX and the dummy pixels DPX defined by the pixel separation pattern 450.

In some example embodiments, as shown in FIG. 4 and FIG. 5, a plurality of active pixel groups PXG may be 2-dimensionally arranged in a plan view in the pixel array area APS, and a plurality of dummy pixel groups DPXG may be 2-dimensionally arranged in the dummy pixel area DR, in a plan view.

Each of an active pixel group PXG and the dummy pixel group DPXG may include N×M active pixels PX in a N×M arrangement and the dummy pixels DPX. The N and the M each may be an integer greater than 1, independently. For example, each of the active pixel group PXG and the dummy pixel group DPXG may include the active pixels PX and the dummy pixels DPX arranged in a matrix shape of a 2×2 form in a plan view. However, the number and arrangement form of the active pixels PX and the dummy pixels DPX included in one active pixel group PXG and the dummy pixel group DPXG is not limited thereto, and may be modified in various ways.

The pixel separation pattern 450 may be located between the active pixels PX and the dummy pixels DPX included in each of the active pixel group PXG and the dummy pixel group DPXG.

The pixel separation pattern 450 may be located between the active pixels PX and the dummy pixels DPX adjacent to each other in the pixel array area APS and the dummy pixel area DR, and may define the active pixels PX and the dummy pixels DPX included in each of the active pixel group PXG and the dummy pixel group DPXG. In a plan view, the pixel separation pattern 450 may have a lattice structure, and in a plan view, may partition each of the active pixel PX and the dummy pixel DPX.

As shown in FIG. 6, the pixel separation pattern 450 may be located within a first trench TR1, on a cross-section. The first trench TR1 may be recessed from the first surface 400a of the substrate 400 toward the second surface 400b. Accordingly, the pixel separation pattern 450 may extend from the first surface 400a of the substrate 400 toward the second surface 400b.

The pixel separation pattern 450 may be a deep trench isolation (DTI) layer. The pixel separation pattern 450 may penetrate the substrate 400. A thickness of the pixel separation pattern 450 may be substantially the same as a thickness along the vertical direction of the substrate 400.

Although FIG. 6 illustrates that the width along the first direction X of the pixel separation pattern 450 is constant within the substrate 400, the shape on cross-section of the pixel separation pattern 450 is not limited thereto, and may be changed in various ways. For example, the pixel separation pattern 450 may have a shape in which the width along the first direction X gradually decreases from the first surface 400a of the substrate 400 to the second surface 400b.

The pixel separation pattern 450 may include a first separation pattern 451, a second separation pattern 453 and a capping pattern 455.

The first separation pattern 451 may extend along an inner side surface of the first trench TR1. The first separation pattern 451 may include a silicon-based insulating material (e.g., silicon nitride, silicon oxide or silicon oxidation nitride) or a high-K material (e.g., hafnium oxide or aluminum oxide). As another example, the first separation pattern 451 may include a plurality of layers, and respective layers may include different materials. The first separation pattern 451 may have a lower refractive index than the substrate 400. However, the material included in the first separation pattern 451 is not limited thereto, and may be changed in various ways. Accordingly, crosstalk phenomena between the pixels PX located in the first substrate 400 may be limited and/or prevented.

The second separation pattern 453 may be located on the first separation pattern 451. That is, both side surfaces of the second separation pattern 453 may be surrounded by the first separation pattern 451. The first separation pattern 451 may be located between the second separation pattern 453 and the substrate 400. The second separation pattern 453 may be spaced apart from the substrate 400 by the first separation pattern 451.

Accordingly, when the image sensor 100 operates, the second separation pattern 453 may be electrically separated from the substrate 400. The second separation pattern 453 may include a crystalline semiconductor material such as polycrystalline silicon, and the second separation pattern 453 may further include a dopant, and the dopant may include the impurities of the first conductivity type or impurities of a second conductivity type. As another example, the second separation pattern 453 may include doped polycrystalline silicon. As a still another example, the second separation pattern 453 may include undoped crystalline semiconductor material. As a still another example, the second separation pattern 453 may include undoped polycrystalline silicon. The term “undoped” may mean that no intentional doping process is to be performed. The dopant may include an N-type dopant and a P-type dopant. However, the material included in the second separation pattern 453 is not limited thereto, and may be changed in various ways.

The capping pattern 455 may be located on a bottom surface of the second separation pattern 453. The second separation pattern 453 and the capping pattern 455 may be located to overlap in the vertical direction, and the capping pattern 455 may be disposed adjacent to the first surface 400a of the substrate 400.

A bottom surface of the capping pattern 455 may be coplanar with the first surface 400a of the substrate 400, and an upper surface of the capping pattern 455 may be coplanar with the bottom surface of the second separation pattern 453.

The capping pattern 455 may include a non-conductive material. The capping pattern 455 may include a silicon-based insulating material (e.g., silicon nitride, silicon oxide or silicon oxidation nitride) or a high-K material (e.g., hafnium oxide or aluminum oxide). However, the material included in the capping pattern 455 is not limited thereto, and may be changed in various ways.

Accordingly, the pixel separation pattern 450 may limit and/or prevent photo-charges generated by the incident light incident on the active pixel PX and the dummy pixel DPX from being incident on another active pixel PX and another dummy pixel DPX adjacent thereto by random drift. That is, the pixel separation pattern 450 may limit and/or prevent crosstalk phenomena between the active pixels PX and between the dummy pixels DPX.

The photodiodes PD to receive the light may be located within the substrate 400. The light incident from the outside may be converted to electrical signals by the photodiodes PD. The photodiodes PD may generate and accumulate photo-charges, proportionally to intensity of the incident light.

A plurality of photodiodes PD may be located to correspond to each of the plurality of active pixels PX included in the plurality of active pixel groups PXG in the pixel array area APS. The plurality of photodiodes PD may be located in the dummy pixel area DR to correspond to each of the plurality of dummy pixels DPX included in the plurality of dummy pixel groups DPXG.

Accordingly, the plurality of photodiodes PD included each of the active pixel group PXG and the dummy pixel group DPXG may have substantially the same arrangement shape in a plan view as the active pixels PX and the dummy pixels DPX.

The photodiodes PD may be a region doped with the impurities of the second conductivity type within the substrate 400. The impurities of the second conductivity type may have an opposite conductivity type to the impurities of the first conductivity type. The impurities of the second conductivity type may include N-type impurities such as phosphorus, arsenic, bismuth, and/or antimony.

Each of the photodiodes PD may include a first region adjacent to the first surface 400a of the substrate 400 and a second region adjacent to the second surface 400b. There may be an impurity concentration difference between the first region and the second region of the photodiodes PD.

Accordingly, the photodiodes PD may have a potential slope between the first surface 400a and the second surface 400b of the substrate 400. However, in some example embodiments, the photodiodes PD may not have a potential slope between the first surface 400a and the second surface 400b of the first substrate 400.

A device isolation pattern 403 may be located within the substrate 400. For example, the device isolation pattern 403 may be located within a second trench TR2, on a cross-section. The second trench TR2 may be recessed from the first surface 400a of the substrate 400 toward the second surface 400b. The device isolation pattern 403 may be a shallow trench isolation (STI) layer.

The device isolation pattern 403 may define an active pattern. An upper surface of the device isolation pattern 403 may be located within the substrate 400. A width of the device isolation pattern 403 along the first direction X may gradually decrease from the first surface 400a of the substrate 400 to the second surface 400b. The upper surface of the device isolation pattern 403 may be located to be spaced apart from the photodiodes PD.

A transmission transistor TX including a transfer gate TG may be located on the first surface 400a of the substrate 400. In some example embodiments, the transfer gate TG may be a Vertical Type. A portion of the transfer gate TG may be located within the substrate 400, and a remaining portion may protrude above the first surface 400a of the substrate 400.

For example, the transfer gate TG may include a first portion TGa located on the first surface 400a of the substrate 400 and a second portion TGb located within the substrate 400 and extending from the first surface 400a of the substrate 400 toward the second surface 400b. However, shape of the transfer gate TG is not limited thereto, and may be changed in various ways. For example, the transfer gate TG may not be provided with the second portion TGb, and may be a Planar Type which only includes the first portion TGa.

Although not shown in FIG. 6 and FIG. 7, an amplification transistor and a selection transistor may be located on the first surface 400a of the substrate 400. That is, the gate of the amplification transistor and the gate of the selection transistor may be located on the first surface 400a of the substrate 400.

Although not shown in FIG. 6 and FIG. 7, a reset transistor and a dual conversion transistor may be located on the first surface 400a of the substrate 400. The reset transistor may include a reset gate, and the dual conversion transistor may include a dual conversion gate.

A gate spacer GS may be located on both side surfaces of the first portion TGa of the transfer gate TG. The gate spacer GS may include, for example, silicon nitride, silicon carbonization nitride or silicon oxidation nitride.

A gate dielectric layer GI may be located between the transfer gate TG and the substrate 400. For example, the gate dielectric layer GI may be located between the second portion TGb and the substrate 400 of the transfer gate TG.

Although not shown in FIG. 6 and FIG. 7, the gate dielectric layer GI may be located between each of the dual conversion gate, and the reset gate described above and the substrate 400, and the gate spacer GS may be located on both side surfaces of the above-described gates.

In some example embodiments, an opposed substrate (not shown) overlapping with the substrate 400 may be further included, and at least one of the amplification transistor, the selection transistor, the reset transistor, and the dual conversion transistor may be located on the opposed substrate (not shown).

In some example embodiments, at least one of the amplification transistor, the selection transistor, the reset transistor, and the dual conversion transistor located on the opposed substrate and the transmission transistor TX located on the substrate 400 may be connected by a connection node (not shown).

A floating diffusion region FD may be located within the substrate 400. The charges charged in the photodiodes PD may be transferred to the floating diffusion region FD. The floating diffusion region FD may maintain the charges transferred from the photodiode PD.

The floating diffusion region FD may be located adjacent to the first surface 400a of the substrate 400. The floating diffusion region FD may be located to be buried from the first surface 400a of the substrate 400 toward the second surface 400b. The floating diffusion region FD may be connected to a first end of the transmission transistor TX.

The first wire region 20 may be located on the first surface 400a of the substrate 400, and may include a plurality of insulation layers IL1, IL2, and IL3, a plurality of wire layers CL1 and CL2 and a via VIA.

The insulation layer may include a first insulation layer IL1, a second insulation layer IL2 and a third insulation layer IL3. The first insulation layer IL1, the second insulation layer IL2, and the third insulation layer IL3 may sequentially stacked on the first surface 400a of the substrate 400.

The first insulation layer IL1 may cover the first surface 400a of the substrate 400. The first insulation layer IL1 may cover the first portion TGa of the transfer gate TG. The second insulation layer IL2 may located on the first insulation layer IL1. The third insulation layer IL3 may located on the second insulation layer IL2.

First insulation layer to third insulation layers IL1, IL2, and IL3 may include an insulating material. For example, the first to third insulation layers IL1, IL2, and IL3 may include a silicon-based insulating material such as silicon oxide, silicon nitride or silicon oxidation nitride.

The first wire region 20 may include a first wire layer CL1 and a second wire layer CL2. The first wire layer CL1 may be located within the second insulation layer IL2. The second wire layer CL2 may be located within the third insulation layer IL3.

A plurality of vias VIA may be located within the first insulation layer IL1, the second insulation layer IL2, the third insulation layer IL3. The vias VIA may interconnect the floating diffusion region FD, the first wire layer CL1 and the second wire layer CL2.

The first wire layer CL1, the second wire layer CL2 and the vias VIA may include a metal material. For example, the first wire layer CL1, the second wire layer CL2 and the vias VIA may include copper (Cu)

The light transmitting layer 30 may be located on the second surface 400b of the substrate 400.

The light transmitting layer 30 may include an insulation structure 320, a color filter CF, a grid pattern 310, the light blocking pattern SP, and microlens layer MLL. The light transmitting layer 30 may collect and filter the light incident from the outside, and provide the light to the photodiodes PD.

The color filter CF may be located on the second surface 400b of the substrate 400.

As shown in FIG. 4 to FIG. 7, the color filter CF may be located in the pixel array area APS and the dummy pixel area DR. The color filter CF may include primary color filters. The color filter CF may include a first color filter CF1, a second color filter CF2 and a third color filter CF3 having different colors. For example, the first color filter CF1 may be a green color filter, and the second color filter CF2 may be a red color filter, and the third color filter CF3 may be a blue color filter.

In some example embodiments, color filters CF located in the pixel array area APS may have a Bayer pattern, in a plan view. That is, the color filters CF may have a pattern in which the number of the first color filter CF1 is about twice as many as the number of the second color filter CF2 or the number of the third color filter CF3.

In some example embodiments, a Bayer pattern may include two first color filters CF1 disposed in diagonal directions to each other and the second color filter CF2 and the third color filter CF3 disposed in diagonal directions to each other, in the color filter CF arranged in a 2×2 format in a plan view on the one active pixel group PXG including the active pixel PX arranged in a 2×2 format in a plan view. That is, in the color filter CF located on the one active pixel group PXG, the ratio of the first color filter CF1, the second color filter CF2, and the third color filter CF may be about 2:1:1.

Each of the first color filter CF1, the second color filter CF2, and the third color filter CF3 may be located to correspond to the plurality of active pixels PX. That is, each of the first color filter CF1, the second color filter CF2, and the third color filter CF3 may be located to overlap with the photodiodes PD located to correspond to each of the plurality of active pixels PX. For example, each of the first color filter CF1, the second color filter CF2, and the third color filter CF3 may be located on the photodiodes PD, and may entirely cover the photodiodes PD.

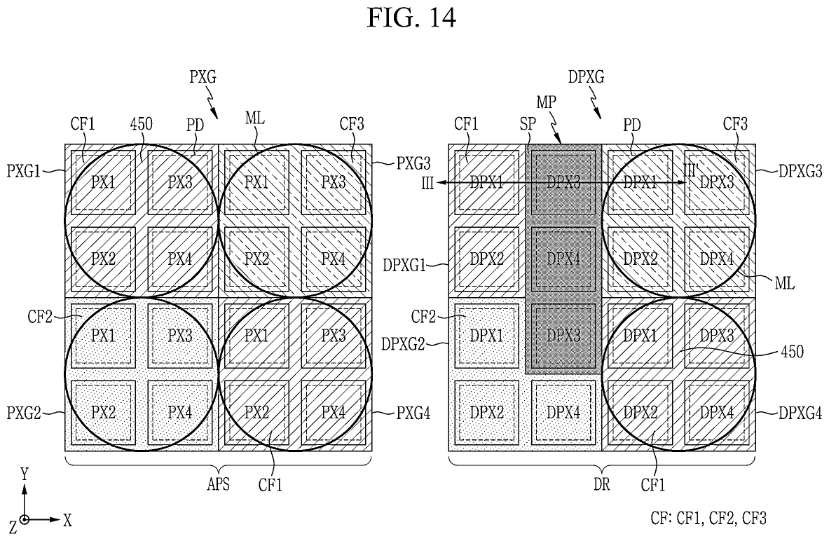

Each of the second color filter CF2 and the third color filter CF3 may be located between the adjacent first color filters CF1. The color filters CF of such Bayer pattern method may be repeatedly arranged along the first direction X and the second direction Y. However, in a plan view, an arrangement form of the color filter CF is not limited thereto, and may be changed in various ways. Detailed description regarding this will be described later with reference to FIG. 14 to FIG. 17.

In some example embodiments, the color filter CF located in the dummy pixel area DR may be located to correspond to only a portion of the plurality of dummy pixels DPX. That is, the color filter CF located in the dummy pixel area DR may be located on only a portion of the plurality of dummy pixels DPX, and may not be located on remaining dummy pixels DPX.

For example, the color filter CF may be located on the dummy pixels DPX that do not overlap with the light blocking pattern SP among the plurality of dummy pixels DPX located in the dummy pixel area DR, and the color filter CF may not be located on the dummy pixels DPX that overlap with the light blocking pattern SP.

Accordingly, a portion of the color filter CF located in the dummy pixel area DR may be substantially the same as the arrangement form of the color filter CF in a plan view located in the pixel array area APS, and a remaining portion may be different from the arrangement form of the color filter CF in a plan view located in the pixel array area APS.

In more detail, as shown in FIG. 5, the dummy pixel area DR may include a first dummy pixel group DPXG1 and a second dummy pixel group DPXG2 that include the at least one dummy pixel DPX overlapping with the light blocking pattern SP, and a third dummy pixel group DPXG3 and a fourth dummy pixel group DPXG4 that do not include the dummy pixel DPX overlapping with the light blocking pattern SP.

Each of the plurality of dummy pixels DPX included in the first dummy pixel group DPXG1 may overlap with the light blocking pattern SP, and the color filter CF may not be located on the first dummy pixel group DPXG1.

A portion of the plurality of dummy pixels DPX included in the second dummy pixel group DPXG2 may overlap with the light blocking pattern SP, and a remaining portion may not overlap with the light blocking pattern SP. The color filter CF may not be located on the dummy pixels DPX overlapping with the light blocking pattern SP among the plurality of dummy pixels DPX included in the second dummy pixel group DPXG2, and the color filter CF may be located on the dummy pixels DPX that does not overlap with the light blocking pattern SP. That is, in the color filter CF located on the second dummy pixel group DPXG2, one among the first color filter CF1, the second color filter CF2, and the third color filter CF3 may be omitted.

Accordingly, the arrangement form of the color filter CF in a plan view located on the second dummy pixel group DPXG2 may be different from the arrangement form of the color filter CF in a plan view located in the pixel array area APS. For example, in the color filter CF located on the second dummy pixel group DPXG2, the third color filter CF3 may be omitted. However, this is merely an example, and the color of the omitted color filter among the color filter CF located on the second dummy pixel group DPXG2 is not limited thereto, and may be changed in various ways according to the arrangement form of the light blocking pattern SP and the dummy pixel DPX.

Each of the plurality of dummy pixels DPX included in each of the third dummy pixel group DPXG3 and the fourth dummy pixel group DPXG4 may not overlap with the light blocking pattern SP, and the arrangement form of the color filter CF in a plan view located on the third dummy pixel group DPXG3 and the fourth dummy pixel group DPXG4 respectively may be substantially the same as the arrangement form of the color filter CF in a plan view located in the pixel array area APS.

As described above, as the color filters CF located in the dummy pixel area DR are located to correspond only to a portion of the plurality of dummy pixels DPX, the color filters CF may be located to be spaced apart in the first direction X or the second direction Y with the light blocking pattern SP interposed between color filters CF. That is, the color filters CF may be located to be spaced apart on both sides of the light blocking pattern SP.

For example, the first color filters CF1 may be located to be spaced apart in the first direction X or the second direction Y with the light blocking pattern SP interposed between first color filters CF1. The second color filters CF2 may be located to be spaced apart in the first direction X with the light blocking pattern SP interposed between color filters CF2.

The insulation structure 320 may be located between the second surface 400b and the color filter CF of the substrate 400 and between the second surface 400b and the light blocking pattern SP of the substrate 400. The insulation structure 320 may limit and/or prevent the reflection of light such that the light incident on the second surface 400b of the substrate 400 may smoothly reach the photodiode PD. The insulation structure 320 may also be called a reflection preventing structure.

The insulation structure 320 may include a first fixed charge layer 321, a second fixed charge layer 323 and a planarization layer 325 that are sequentially stacked on the second surface 400b of the substrate 400.

Each of the first fixed charge layer 321, the second fixed charge layer 323, and the planarization layer 325 may include different materials. The first fixed charge layer 321 may include at least one of aluminum oxide, tantalum oxide, titanium oxide, and hafnium oxide.

The second fixed charge layer 323 may include another one of aluminum oxide, tantalum oxide, titanium oxide and hafnium oxide. For example, the first fixed charge layer 321 may include aluminum oxide, the second fixed charge layer 323 may include hafnium oxide, and the planarization layer 325 may include silicon oxide.

Although not shown in FIG. 6 and FIG. 7, in some example embodiments, silicon anti-reflection layer (not shown) may be further located between the second fixed charge layer 323 and the planarization layer 325. The anti-reflection layer may include, for example, silicon nitride.

The grid pattern 310 may be located on the insulation structure 320. The grid pattern 310 may be located between the color filters CF adjacent to each other. The grid pattern 310 may be located on an interface between the color filters CF adjacent to each other, and may separate the color filters CF adjacent to each other. The grid pattern 310 may be located on the pixel separation pattern 450, and may overlap with at least a portion of the pixel separation pattern 450 in the third direction Z, which is the vertical direction.

An upper surface of the grid pattern 310 may be covered by the color filters CF adjacent to each other. For example, a portion of the upper surface of the grid pattern 310 may be covered by the first color filter CF1, and a remaining portion may be covered by the second color filter CF2. However, arrangement relationship between the grid pattern 310 and the color filter CF is not limited thereto, and may be changed in various ways.

The grid pattern 310 may be located in the pixel array area APS and the dummy pixel area DR, and may have a lattice structure in a plan view. The grid pattern 310 may surround the color filters CF, the active pixels PX, and the dummy pixels DPX, in a plan view.

The grid pattern 310 may include a first grid pattern 311 and a second grid pattern 313 sequentially stacked. A thickness of the first grid pattern 311 along the third direction Z may be different from a thickness of the second grid pattern 313 along the third direction Z.

For example, the thickness of the first grid pattern 311 along the third direction Z may be less than the thickness of the second grid pattern 313 along the third direction Z. However, relationship between a thickness of the first grid pattern 311 and a thickness of the second grid pattern 313 is not limited thereto, and may be changed in various ways.

In some example embodiments, the first grid pattern 311 and the second grid pattern 313 may include at least one of metal material, metal nitride, and a material having lower refractive index than the color filter CF. For example, the first grid pattern 311 and the second grid pattern 313 may include at least one of organic materials such as a polymer layer including titanium (Ti), titanium nitride (TiN), tungsten (W), aluminum (Al), copper (Cu), and silica nano particles. However, the material included in the first grid pattern 311 and the second grid pattern 313 is not limited thereto, and may be changed in various ways.

When the first grid pattern 311 and/or the second grid pattern 313 includes the material having lower refractive index than the color filter CF, the amount of light incident on the photodiodes PD may be increased, and crosstalk between the active pixels PX and/or between the dummy pixels DPX may be reduced. That is, in each of the photodiodes PD, light receiving efficiency may be increased, and signal-noise ratio (SNR) characteristic may be improved.

Although FIG. 6 and FIG. 7 illustrate that the grid pattern 310 is formed as two layers, the number of layers included in the grid pattern 310 is not limited thereto, and may be changed in various ways. For example, the grid pattern 310 may be configured as a single layer, and the grid pattern 310 may include the same material as the first grid pattern 311 and the second grid pattern 313 described above. As another example, the grid pattern 310 may be configured as a at least three or more multi-layer, and each layer included in the grid pattern 310 may include the same material as the first grid pattern 311 and the second grid pattern 313 described above.

The light blocking pattern SP may be located in the dummy pixel area DR. That is, the light blocking pattern SP may not be located in the pixel array area APS, and may be located only in the dummy pixel area DR. The light blocking pattern SP may be located to overlap with at least one of the plurality of dummy pixels DPX located in the dummy pixel area DR in the vertical direction.

In more detail, the light blocking pattern SP may be located on the insulation structure 320. The light blocking pattern SP may be located to overlap with at least one of the photodiodes PD located to correspond to each of the plurality of dummy pixels DPX located in the dummy pixel area DR, in the third direction Z, which is the vertical direction.

The light blocking pattern SP may entirely cover the photodiode PD. The light blocking pattern SP may entirely cover the photodiode PD, and may be located to overlap along the third direction Z (e.g., the vertical direction) with the pixel separation pattern 450 located on both sides of the photodiodes PD.

A portion of the pixel separation pattern 450 located in the dummy pixel area DR may overlap with the grid pattern 310 described above in the third direction Z, which is the vertical direction, and a remaining portion may overlap with the light blocking pattern SP in the third direction Z, which is the vertical direction. For example, in the dummy pixel area DR, the light blocking pattern SP instead of the grid pattern 310 may be located on the pixel separation pattern 450.

The light blocking pattern SP located in the dummy pixel area DR may be located between the color filters CF. That is, in the dummy pixel area DR, a portion of the color filters CF may be located to be spaced apart with the light blocking pattern SP interposed between color filters CF.

A partial region of the light blocking pattern SP may overlap with the color filter CF, and a remaining region may not overlap with the color filter CF. An edge portion of the light blocking pattern SP may be located between the insulation structure 320 and the color filter CF, and may overlap with the color filter CF. That is, the edge portion of the light blocking pattern SP may be covered by the color filter CF. A central portion of the light blocking pattern SP may not overlap with the color filter CF in the third direction Z, which is the vertical direction.

An area of an upper surface of the light blocking pattern SP overlapping with the color filter CF may be smaller than an area of an upper surface of the light blocking pattern SP that does not overlap with the color filter CF. That is, most of the upper surface of the light blocking pattern SP may not overlap with the color filter CF in the third direction Z, which is the vertical direction. However, arrangement relationship between the light blocking pattern SP and the color filter CF is not limited thereto, and may be changed in various ways. For example, the light blocking pattern SP may be located not to overlap with the color filter CF in the third direction Z, which is the vertical direction.

In some example embodiments, the light blocking pattern SP may include a material for blocking the light from being incident on the photodiodes PD. The light blocking pattern SP may include a metal material. For example, the light blocking pattern SP may include the same material as the first grid pattern 311 of the grid pattern 310 described above. That is, the light blocking pattern SP may include at least one of metal material or metal nitride. For example, the light blocking pattern SP may include at least one of titanium (Ti), titanium nitride (TiN), tungsten (W), aluminum (Al), and copper (Cu). However, the material included in the light blocking pattern SP is not limited thereto, and may be changed in various ways. For example, the light blocking pattern SP may include a different metal material from the first grid pattern 311.

As shown in FIG. 6 and FIG. 7, a thickness of the light blocking pattern SP along the third direction Z may be different from a thickness of the grid pattern 310 along the third direction Z. For example, the thickness of the light blocking pattern SP along the third direction Z may be thinner than the thickness of the grid pattern 310 along the third direction Z. That is, an upper surface SP_T of the light blocking pattern SP may be located at a level lower than upper surface 310_T of the grid pattern 310.

The thickness of the light blocking pattern SP along the third direction Z may be thinner than a thickness of the color filter CF along the third direction Z. That is, the upper surface SP_T of the light blocking pattern SP may be located at a level lower than upper surface CF_T of the color filter CF.

In some example embodiments, the light blocking pattern SP may have a first thickness h1 along the third direction Z, the first grid pattern 311 may have a second thickness h2 along the third direction Z, and the first thickness h1 may be substantially the same as the second thickness h2.

When the light blocking pattern SP may have a thickness along the third direction Z that is substantially the same as the first grid pattern 311, the thickness of the light blocking pattern SP along the third direction Z may be thinner than the thickness of the second grid pattern 313 along the third direction Z. However, the thickness relationship between the light blocking pattern SP and the first grid pattern 311 is not limited thereto, and may be changed in various ways. For example, the thickness h1 of the light blocking pattern SP along the third direction Z may be thicker than the thickness h2 of the first grid pattern 311 along the third direction Z.

As shown in FIG. 6 and FIG. 7, the microlens layer MLL may be located on the color filter CF and the light blocking pattern SP. The microlens layer MLL may include a plurality of microlenses ML located to correspond to the color filter CF and a flat portion MLP located to correspond to the light blocking pattern SP. The microlens ML and the flat portion MLP may include the same material, and may be integrally configured.

Unlike an upper surface MLP_T of the flat portion MLP, an upper surface ML_T of the microlens ML may include a convexly curved surface in order to refract and collect the light incident from the outside. However, shape of the microlens ML is not limited thereto, and may be changed in various ways. For example, the upper surface ML_T of the microlens ML may have a quadrangle form having round edges.

The flat portion MLP of the microlens layer MLL may correspond to a portion remaining after removing the microlens ML from the microlens layer MLL. The upper surface MLP_T of the flat portion MLP may have a substantially flat surface. The upper surface MLP_T of the flat portion MLP may be located at a level lower than the upper surface ML_T of the microlens ML.

In more detail, as shown in FIG. 4 to FIG. 7, in the pixel array area APS, the microlenses ML of the microlens layer MLL may be located to correspond to the color filters CF that overlap with each of the plurality of active pixels PX.

The microlens ML may be located on the color filter CF corresponding to each of the plurality of active pixels PX in the pixel array area APS. That is, in the pixel array area APS, the microlenses ML may be arranged on the one active pixel group PXG, in a 2×2 arrangement format in a plan view. For example, the number of the color filters CF and the microlens ML located on the one active pixel group PXG may be substantially the same.

In the dummy pixel area DR, the microlenses ML of the microlens layer MLL may located to correspond to the color filters CF that overlap with the dummy pixels DPX, and may not be located on the dummy pixels DPX that overlap with the light blocking pattern SP. That is, the microlenses ML located in the dummy pixel area DR may not be located on the light blocking pattern SP. For example, the plurality of microlenses ML located in the dummy pixel area DR may be located to be spaced apart in the first direction X or the second direction Y with the light blocking pattern SP interposed between microlenses ML.

Accordingly, the microlenses ML located in a portion of the dummy pixel area DR may be substantially the same as an arrangement form of the microlens ML in a plan view located in the pixel array area APS, and a remaining portion may be different from the arrangement form of the microlens ML in a plan view located in the pixel array area APS.

In more detail, as shown in FIG. 5, the microlens ML may not be located on the light blocking pattern SP located to correspond to the plurality of dummy pixels DPX included in the first dummy pixel group DPXG1. Although not shown in FIG. 5, a flat portion (refer to ‘MLP’ of FIG. 6) of a microlens layer (refer to ‘MLL’ of FIG. 6) may be located on the light blocking pattern SP located to correspond to the plurality of dummy pixels DPX included in the first dummy pixel group DPXG1.

A portion of the plurality of dummy pixels DPX included in the second dummy pixel group DPXG2 may overlap with the light blocking pattern SP, and a remaining portion may overlap with the color filters CF. The microlenses ML of the microlens layer MLL may not be located on the light blocking pattern SP located to correspond to the plurality of dummy pixels DPX, and may be located on the color filters CF located to correspond to each of the plurality of dummy pixels DPX. Although not shown in FIG. 5, a flat portion (refer to ‘MLP’ of FIG. 6) of a microlens layer (refer to ‘MLL’ of FIG. 6) may be located on the light blocking pattern SP located to correspond to the plurality of dummy pixels DPX.

Each of the plurality of dummy pixels DPX included in the third dummy pixel group DPXG3 and the fourth dummy pixel group DPXG4 may overlap with the color filters CF. The microlenses ML of the microlens layer MLL may be located on the color filters CF located to correspond to each of the plurality of dummy pixels DPX. That is, the arrangement form of the microlens ML in a plan view located on the color filter CF located in the third dummy pixel group DPXG3 and the fourth dummy pixel group DPXG4 may be substantially the same as the arrangement form of the microlens ML in a plan view located in the pixel array area APS.

As shown in FIG. 6 and FIG. 7, a partial region of the light blocking pattern SP located in the dummy pixel area DR may overlap with the microlenses ML of the microlens layer MLL, and a remaining region may overlap with the flat portion MLP. The edge portion of the light blocking pattern SP may overlap with the microlenses ML of the microlens layer MLL in the third direction Z, which is the vertical direction. The central portion of the light blocking pattern SP may not overlap with the flat portion MLP of the microlens layer MLL in the third direction Z, which is the vertical direction. However, arrangement relationship of the light blocking pattern SP, the microlens ML, and the flat portion MLP is not limited thereto, and may be changed in various ways. For example, the light blocking pattern SP may be located not to overlap with the microlenses ML of the microlens layer MLL in the third direction Z, which is the vertical direction.

The edge portion of the light blocking pattern SP may be covered by the color filter CF, and the central portion of the light blocking pattern SP may be covered by the flat portion MLP of the microlens layer MLL. That is, the light blocking pattern SP may be in direct contact with the color filter CF and the flat portion MLP of the microlens layer MLL. However, arrangement relationship of the light blocking pattern SP, the color filter CF, and the flat portion MLP of the microlens layer MLL is not limited thereto, and may be changed in various ways. For example, the upper surface of the light blocking pattern SP may not overlap with the color filter CF, and the upper surface of the light blocking pattern SP may be entirely covered by the flat portion MLP of the microlens layer MLL. As another example, another layer may be further located in at least one of between the light blocking pattern SP and the color filter CF and between the flat portion MLP of the microlens layer MLL and the light blocking pattern SP.

According to the image sensor 100 according to some example embodiments, as the mark pattern MP configured as the light blocking pattern SP overlapping with the at least one of the plurality of dummy pixels DPX located in the dummy pixel area DR is formed, the location of the defect pixel included in the pixel array area APS may be specified.

As the mark pattern MP is configured as the light blocking pattern SP, and the color filter CF and the microlens ML are located not to cover the light blocking pattern SP, visibility with respect to the mark pattern MP on the appearance may be improved.

As the mark pattern MP is configured as the light blocking pattern SP, the external light may be limited and/or prevented from being incident on the photodiode PD, and due to this, visibility with respect to the mark pattern MP may also be improved on an output image of the dummy pixel area DR.

Accordingly, in the pixel array area APS, the location of the defective pixel included in the plurality of active pixels PX may be accurately specified such that reliability and productivity of the image sensor 100 may be improved.

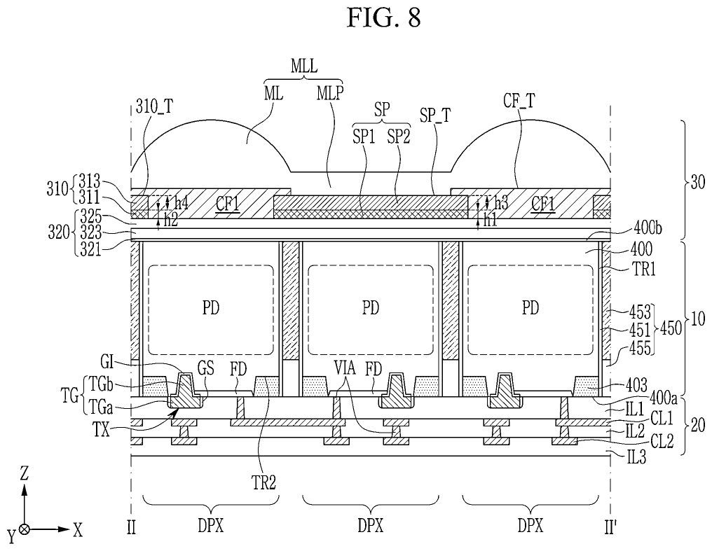

Hereinafter, referring to FIG. 8 to FIG. 17, image sensors according to some example embodiments will be described. In the following, the same reference numerals refer to components identical to those of previously described, and redundant descriptions will be omitted or simplified, and description will focus on differences.

FIG. 8 to FIG. 13 are cross-sectional views taken along line II-II′ of FIG. 4 according to some example embodiments.

According to some example embodiments shown in FIG. 8, unlike some example embodiments described with respect to FIG. 7, a difference lies in that the light blocking pattern SP has a multi-layer structure.

In more detail, referring to FIG. 8, the light blocking pattern SP may include a first light blocking pattern SP1 and a second light blocking pattern SP2 that are sequentially located on the insulation structure 320.

In some example embodiments, the first light blocking pattern SP1 and the second light blocking pattern SP2 may include different materials. The first light blocking pattern SP1 may include the same material as the first grid pattern 311 of the grid pattern 310, and the second light blocking pattern SP2 may include the same material as the second grid pattern 313.

In some example embodiments, the first light blocking pattern SP1 may be formed by substantially the same process as the first grid pattern 311, and the second light blocking pattern SP2 may be formed by substantially the same process as the second grid pattern 313. However, the method for forming the grid pattern 310 and the light blocking pattern SP is not limited thereto, and may be changed in various ways.

In some example embodiments, the first grid pattern 311 and the first light blocking pattern SP1 may include at least one of metal material or metal nitride. For example, the first grid pattern 311 and the first light blocking pattern SP1 may include at least one of titanium (Ti), titanium nitride (TiN), tungsten (W), aluminum (AI), and copper (Cu).

The second grid pattern 313 and the second light blocking pattern SP2 may include the material having lower refractive index than the color filter CF. For example, the second grid pattern 313 and the second blocking pattern SP2 may include an organic material such as a polymer layer including silica nano particles. However, the material included in the first light blocking pattern SP1 and the second light blocking pattern SP2 is not limited thereto, and may be changed in various ways. For example, the first light blocking pattern SP1 and the second light blocking pattern SP2 may include the same material. As another example, the first light blocking pattern SP1 may include a different material from the first grid pattern 311, and the second light blocking pattern SP2 may include a different material from the second grid pattern 313. As a still another example, the first light blocking pattern SP1 may include the same material as the first grid pattern 311, and the second light blocking pattern SP2 may include a different material from the second grid pattern 313.

The first light blocking pattern SP1 may have the first thickness h1 along the third direction Z, and the first grid pattern 311 may have the second thickness h2 along the third direction Z. The second light blocking pattern SP2 may have a third thickness h3 along the third direction Z, and the second grid pattern 313 may have a fourth thickness h4 along the third direction Z.

In some example embodiments, the first thickness h1 and the third thickness h3 may be different. For example, the first thickness h1 may be thinner than the third thickness h3. That is, a thickness of the first light blocking pattern SP1 along the third direction Z may be thinner than a thickness of the second light blocking pattern SP2 along the third direction Z. However, the relationship between the first thickness h1 and the third thickness h3 is not limited thereto, and may be changed in various ways.

In some example embodiments, the first thickness h1 may be substantially the same as the second thickness h2, and the third thickness h3 may be substantially the same as the fourth thickness h4. That is, an upper surface of the first light blocking pattern SP1 and an upper surface of the first grid pattern 311 may be located at substantially the same level, and an upper surface of the second light blocking pattern SP2 may be located at substantially the same level as an upper surface of the second grid pattern 313.

A sum of the first thickness h1 and the third thickness h3 may be substantially the same as a sum of the second thickness h2 and the fourth thickness h4. That is, the upper surface SP_T of the light blocking pattern SP may be located at substantially the same level as the upper surface 310_T of the grid pattern 310. However, the relationship between the first thickness h1, the second thickness h2, the third thickness h3, and the fourth thickness h4 is not limited thereto, and may be changed in various ways. For example, the first thickness h1 may be different from the second thickness h2, and the third thickness h3 may be different as the fourth thickness h4. As another example, the first thickness h1 may be substantially the same as the second thickness h2, and the third thickness h3 may be different from the fourth thickness h4. As a still another example, the first thickness h1 and the second thickness h2 may be different, and the third thickness h3 and the fourth thickness h4 may be substantially the same.

According to an image sensor according to some example embodiments described with respect to FIG. 8, substantially the same effect as image sensors according to some example embodiments previously described may be obtained. Furthermore, as the light blocking pattern SP includes the material having lower refractive index than the color filter CF, crosstalk between the dummy pixels DPX may be reduced such that light receiving efficiency of the photodiodes PD located adjacent to the light blocking pattern SP may be improved.

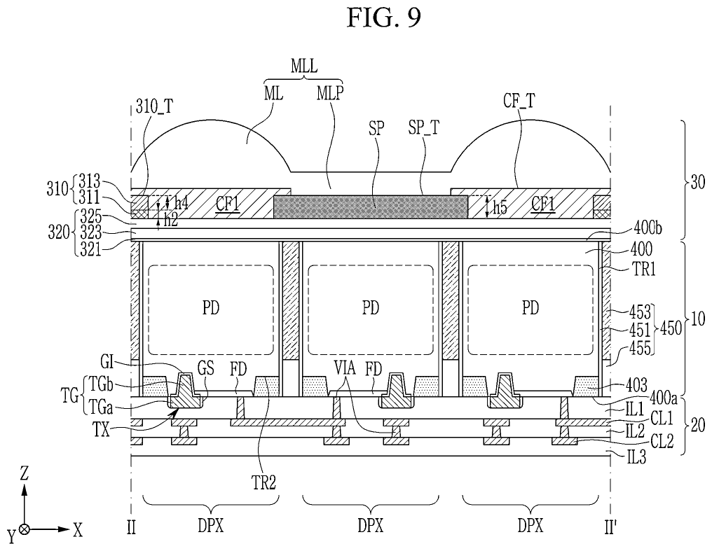

According to some example embodiments described with respect to FIG. 9, unlike the light blocking pattern SP according to some example embodiments described with respect to FIG. 7, a difference lies in that the thickness of the light blocking pattern SP along the third direction Z may be different.

In more detail, referring to FIG. 9, the first grid pattern 311 may have the second thickness h2 along the third direction Z, and the second grid pattern 313 may have the fourth thickness h4 along the third direction Z, and the light blocking pattern SP may have a fifth thickness h5 along the third direction Z.

In some example embodiments, the second thickness h2, the fourth thickness h4, and the fifth thickness h5 may be different. For example, the second thickness h2 may be thinnest, and the fifth thickness h5 may be thickest. The fourth thickness h4 may be thicker than the second thickness h2, and may be thinner than the fifth thickness h5. That is, a thickness h5 of the light blocking pattern SP along the third direction Z may be thicker than each of the thickness h2 along the third direction Z of the first grid pattern 311 and the thickness h4 along and the third direction Z of the second grid pattern 313.

The sum of the second thickness h2 and the fourth thickness h4 may be substantially the same as the fifth thickness h5. That is, the upper surface SP_T of the light blocking pattern SP and the upper surface 310_T of the grid pattern 310 may be located at substantially the same level. However, the relationship between the second thickness h2, the fourth thickness h4, and the fifth thickness h5 is not limited thereto, and may be changed in various ways.

In some example embodiments, the first grid pattern 311 and the second grid pattern 313 may include a metal material. For example, the first grid pattern 311 may include at least one of titanium (Ti) and titanium nitride (TiN), and the second grid pattern 313 may include tungsten (W).

In some example embodiments, when the first grid pattern 311 and the second grid pattern 313 includes metal material, the light blocking pattern SP may include a first one among the same material as the first grid pattern 311 and the second grid pattern 313. For example, the light blocking pattern SP may include the same material as the first grid pattern 311, and the thickness h5 of the light blocking pattern SP along the third direction Z may be thicker than the thickness h2 of the first grid pattern 311 along the third direction Z. The light blocking pattern SP and the first grid pattern 311 may include, for example, at least one of titanium (Ti) and titanium nitride (TiN).

As another example, the light blocking pattern SP may include the same material as the second grid pattern 313, and the thickness h5 of the light blocking pattern SP along the third direction Z may be thicker than or substantially the same as the thickness h4 of the second grid pattern 313 along the third direction Z. The light blocking pattern SP and the second grid pattern 313 may include, for example, tungsten (W).

In some example embodiments, the light blocking pattern SP may include a different material from the grid pattern 310. That is, the light blocking pattern SP may include a different material from the first grid pattern 311 and the second grid pattern 313.

The light blocking pattern SP may include a non-metal material. The light blocking pattern SP may include a material including a light absorption material. For example, the light blocking pattern SP may include an inorganic black pigment or organic black pigment. The inorganic black pigment may be a carbon black, and organic black pigment may include at least one of lactam black, perylene black, and aniline black, but the material included in the light blocking pattern SP is not limited thereto, and may be changed in various ways.

In some example embodiments, the light blocking pattern SP may include an organic material having a high reflective ratio. For example, the light blocking pattern SP may include at least one of PET, PI, and PC.

According to image sensors according to some example embodiments described with respect to FIG. 9, image sensors having substantially the same effect as image sensors according to some example embodiments previously described may also be provided.

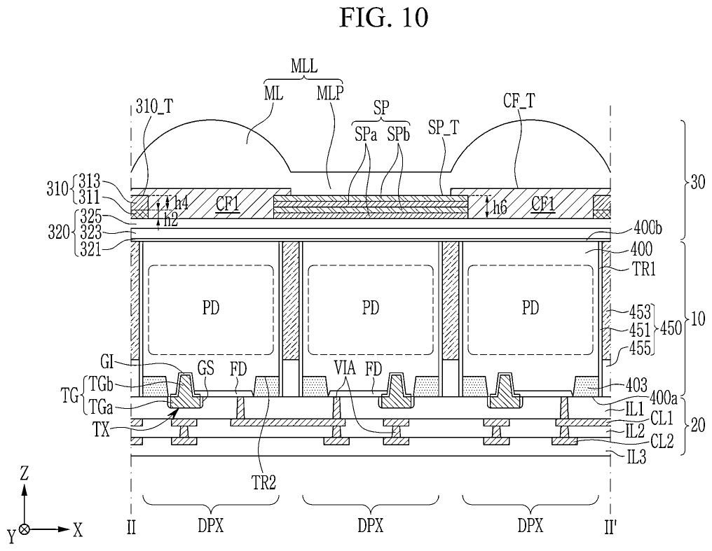

According to some example embodiments described with respect to FIG. 10, unlike the light blocking pattern SP according to some example embodiments described with respect to FIG. 7, a difference lies in that the light blocking pattern SP is configured as multi-layers.

In more detail, referring to FIG. 10, the light blocking pattern SP may have a multi-layer structure including a first refractive layer SPa and a second refractive layer SPb having different refractive indices.

A refractive index of the first refractive layer SPa of the light blocking pattern SP may be lower than a refractive index of the second refractive layer SPb. That is, the first refractive layer SPa may correspond to a low refractive layer, and the second refractive layer SPb may correspond to a high refractive layer. For example, the refractive index of the first refractive layer SPa may be about 1.4 to 1.6, and the refractive index of the second refractive layer SPb may be about 1.6 to 2.5. However, this is merely an a example, and each of the first refractive layer SPa and the refractive index of the second refractive layer SPb is not limited to the above numerical range, and may be changed in various ways.

The first refractive layer SPa may include a dielectric material having a high refractive index and a low absorption rate in the visible light band, such as, for example, TiO₂, GaN, SiN₃, ZnS, ZnSe, Si₃N₄, or the like. The second refractive layer SPb may include a dielectric material having a low refractive index and a low absorption rate in the visible light band, such as, SiO₂, siloxane-based spin-on-glass (SOG), or the like. However, the material included in the first refractive layer SPa and the second refractive layer SPb is not limited thereto, and may be changed in various ways.

In some example embodiments, the first refractive layer SPa and the second refractive layer SPb of the light blocking pattern SP may be alternately stacked along the third direction Z on the insulation structure 320. That is, the light blocking pattern SP may include at least one first refractive layer SPa and at least one second refractive layer SPb.

Although FIG. 10 illustrates that the light blocking pattern SP includes two first refractive layers SPa and two second refractive layers SPb, the number and their arrangement relationship of the first refractive layer SPa and the second refractive layer SPb included in the light blocking pattern SP is not limited thereto, and may be changed in various ways.

Although FIG. 10 illustrates that the number of the first refractive layer SPa and the number of the second refractive layer SPb included in the light blocking pattern SP are the same, but is not limited thereto, and in some example embodiments, the number of the first refractive layer SPa and the number of the second refractive layer SPb included in the light blocking pattern SP may be different.

In some example embodiments, as the light blocking pattern SP has a structure in which the first refractive layer SPa corresponding to the low refractive layer and the second refractive layer SPb corresponding to the high refractive layer are alternately repeated, as the light incident on the light blocking pattern SP is reflected due to repeated total reflection on the first refractive layer SPa and the second refractive layer SPb, the external light may be blocked.

When the light is incident on the first refractive layer SPa corresponding to the low refractive layer by passing through the second refractive layer SPb corresponding to the high refractive layer, reflection may occur on the interface between them.

The light incident on the first refractive layer SPa by more than a predetermined angle may be totally reflected, and the angle range of the total reflection may be wider as the refractive index difference between the first refractive layer SPa and the second refractive layer SPb is greater. Since the first refractive layer SPa has a lower refractive index than the second refractive layer SPb, the reflection ratio of light on a surface of the first refractive layer SPa may be high, and due to this, the light may be blocked from being incident on the photodiode PD located to overlap with the light blocking pattern SP.

The path of the light incident on the light blocking pattern SP may be changed or the light may be scattered while passing through a plurality of first refractive layers SPa and the second refractive layers SPb, thereby possibly being extracted back to the outside.

As such, when the light blocking pattern SP is formed as the plurality of first refractive layers SPa and a plurality of second refractive layers SPb, the light may be blocked from being incident on the photodiodes PD that overlap with the light blocking pattern SP, and simultaneously, the light may be incident on the photodiodes PD that do not overlap with the light blocking pattern SP by changing the path of light, such that the light receiving efficiency may be improved.

In some example embodiments, the first grid pattern 311 may have the second thickness h2 along the third direction Z, and the second grid pattern 313 may have the fourth thickness h4 along the third direction Z, and the light blocking pattern SP may have a sixth thickness h6 along the third direction Z.

Here, the sixth thickness h6 may be substantially the same as a grand sum of thicknesses of the plurality of first refractive layers SPa and the plurality of second refractive layers SPb included in the light blocking pattern SP.

In some example embodiments, the sum of the second thickness h2 and the fourth thickness h4 may be substantially the same as the sixth thickness h6. That is, the upper surface 310_T of the grid pattern 310 may be located at substantially the same level the upper surface SP_T of the light blocking pattern SP. However, the relationship between the sum of the second thickness h2 and the fourth thickness h4 and the sixth thickness h6 is not limited thereto, and may be changed in various ways. For example, the sum of the second thickness h2 and the fourth thickness h4 may be different from the sixth thickness h6. That is, the upper surface 310_T of the grid pattern 310 may be located at a different level from the upper surface SP_T of the light blocking pattern SP.

Although FIG. 10 illustrates that a thickness along the third direction Z of each of the first refractive layer SPa and the second refractive layer SPb included in the light blocking pattern SP is substantially the same, the thickness relationship between the first refractive layer SPa and the second refractive layer SPb is not limited thereto, and may be changed in various ways. For example, in order to reflect the light incident on the light blocking pattern SP to the outside, a thickness of the first refractive layer SPa and a thickness of the second refractive layer SPb may formed to be different.

According to an image sensor according to some example embodiments described with respect to FIG. 10, substantially the same effect as image sensors according to some example embodiments previously described may be obtained. Furthermore, as the light blocking pattern SP reflects the light incident from the outside and at the same time, the path of the light incident from the outside is changed or scattered such that the light is incident on the photodiodes PD that do not overlap with the light blocking pattern SP, the light receiving efficiency may be improved.

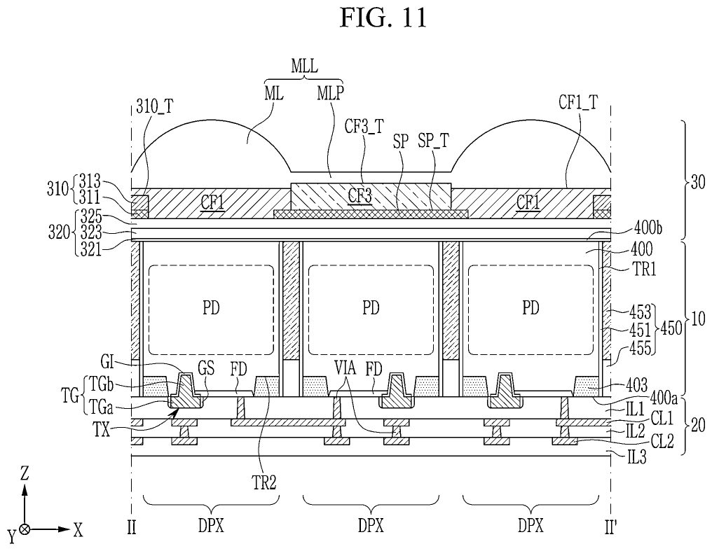

Referring to FIG. 11, unlike some example embodiments described with respect to FIG. 7, a difference lies in that the third color filter CF3 is located on the light blocking pattern SP.

Referring to FIG. 11, in some example embodiments, the third color filter CF3 may be located on the light blocking pattern SP. The light blocking pattern SP may overlap with a plurality of color filters CF1 and CF3 in the third direction Z, which is the vertical direction. For example, the edge portion of the light blocking pattern SP may overlap with the first color filter CF1, and the central portion of the light blocking pattern SP may overlap with the third color filter CF3. An interface between the first color filter CF1 and the third color filter CF3 may be located at both side edge portions of the light blocking pattern SP.

Accordingly, the upper surface SP_T of the light blocking pattern SP may be entirely covered by the first color filters CF1 and the third color filter CF3. However, this is merely an example, and the number and color of the color filters overlapping with the light blocking pattern SP is not limited thereto, and may be changed in various ways. For example, the light blocking pattern SP may not overlap with the first color filters CF in the third direction Z, which is the vertical direction, and may be entirely covered by the third color filter CF3.

In some example embodiments, as the third color filter CF3 is located on the light blocking pattern SP, the arrangement form of color filter (refer to ‘CF’ of FIG. 4) in a plan view located in the dummy pixel area DR may be substantially the same as the arrangement form of the color filter CF in a plan view located in the pixel array area APS described above with reference to FIG. 4.

In some example embodiments, as the third color filter CF3 as shown in FIG. 11 is located on the light blocking pattern SP, the microlenses ML of the microlens layer MLL are located on a portion of the color filters CF1 and CF3, and the flat portion MLP of the microlens layer MLL may be located on a remaining portion. For example, the microlenses ML of the microlens layer MLL may be located on the first color filters CF1 located to be spaced apart with the light blocking pattern SP interposed between first color filters CF1, and first color filters CF1 may be located to overlap with the both side edge portions of the light blocking pattern SP, and the flat portion MLP of the microlens layer MLL may be located on the third color filter CF3 located on the central portion of the light blocking pattern SP.

Accordingly, the light blocking pattern SP may be located to be spaced apart from the flat portion MLP of the microlens layer MLL in the third direction Z, with the third color filter CF3 interposed between the flat portion MLP and the light blocking pattern SP. That is, a bottom surface of the third color filter CF3 may be in direct contact with the light blocking pattern SP, and an upper surface of the third color filter CF3 may be in direct contact with the flat portion MLP of the microlens layer MLL. For example, the upper surface of the third color filter CF3 may be entirely covered by the flat portion MLP of the microlens layer MLL.

In some example embodiments, upper surfaces CF1_T and CF3_T of the first color filter CF1 and the third color filter CF3 located on the light blocking pattern SP may be located at different levels.

For example, the upper surface CF1_T of the first color filter CF1 located in the both side edge portions of the light blocking pattern SP may be located at a level lower than upper surface CF3_T of the third color filter CF3 located in the central portion of the light blocking pattern SP.

This may be the result of the third color filter CF3 being formed on the light blocking pattern SP. However, the arrangement relationship of the upper surfaces CF1_T and CF3_T of the first color filter CF1 and the third color filter CF3 is not limited thereto, and may be changed in various ways. For example, the upper surface CF1_T of the first color filter CF1 located in the both side edge portions of the light blocking pattern SP and the upper surface CF3_T of the third color filter CF3 located in the central portion of the light blocking pattern SP may be located at substantially the same level, and the upper surfaces CF1_T and CF3_T of the color filter CF may be substantially flat.

According to an image sensor according to some example embodiments described with respect to FIG. 11, substantially the same effect as image sensors according to some example embodiments previously described may be obtained. That is, since the color filter CF overlapping with the central portion of the light blocking pattern SP may be distinguished from the color filter CF overlapping with the edge portion of the light blocking pattern SP, visibility with respect to the mark pattern MP configured as the light blocking pattern SP on the appearance and on the output image may be improved.

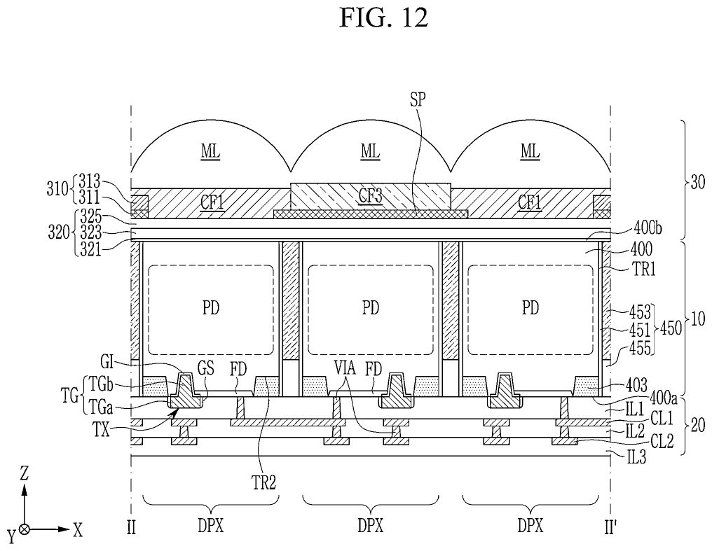

According to some example embodiments described with respect to FIG. 12, unlike some example embodiments described with respect to FIG. 11, a difference lies in that the third color filter CF3 and the microlens ML are located on the light blocking pattern SP.

In more detail, referring to FIG. 12, unlike some example embodiments described with respect to FIG. 11, the microlenses ML of the microlens layer MLL may be located on the third color filter CF3 located on the central portion of the light blocking pattern SP.

In some example embodiments, the microlens ML may be located to correspond to each of the plurality of color filters CF1 and CF3. For example, the microlens ML may be located to correspond to each of the first color filters CF1 overlapping with the both side edge portions of the light blocking pattern SP and the third color filter CF3 overlapping with the central portion of the light blocking pattern SP. That is, the microlens ML may be located to overlap with each of the plurality of color filters CF1 and CF3.

In some example embodiments, as the microlens ML is located to correspond to each of the plurality of color filters CF1 and CF3, the arrangement form of the microlens ML in a plan view located in the dummy pixel area DR may be substantially the same as the arrangement form of the microlens ML in a plan view located in the pixel array area APS described above with reference to FIG. 4.

In some example embodiments, an upper surface of each of the plurality of microlenses ML located to correspond to each of the plurality of color filters CF1 and CF3 may be located at substantially the same level. For example, an upper surface of the microlens ML located on the first color filters CF1 located to overlap with the both side edge portions of the light blocking pattern SP may be located at substantially the same level as the upper surface of the microlens ML located on the third color filter CF3 located to overlap with the central portion of the light blocking pattern SP. However, arrangement relationship of the upper surface of the microlenses ML is not limited thereto, and may be changed in various ways. For example, the upper surface of the microlens ML located on the first color filters CF1 located to overlap with the both side edge portions of the light blocking pattern SP may be located at a level lower than the upper surface of the microlens ML located on the third color filter CF3 located to overlap with the central portion of the light blocking pattern SP.

According to an image sensor according to some example embodiments described with respect to FIG. 12, substantially the same effect as image sensors according to some example embodiments described with respect to FIG. 11 may be obtained.

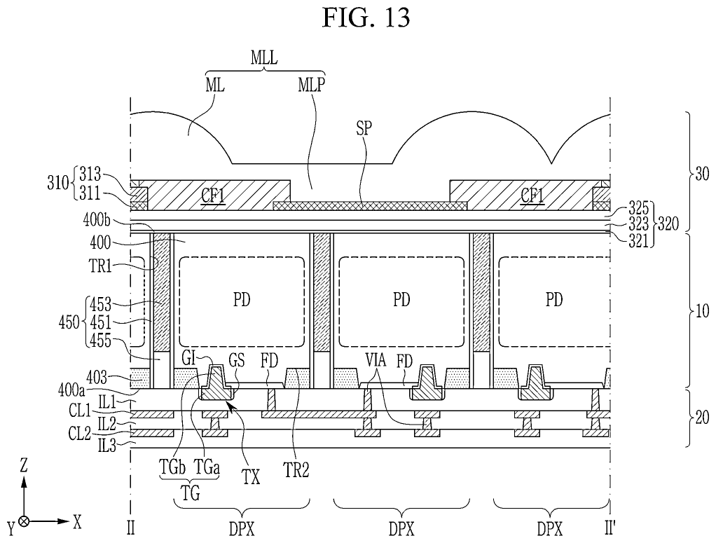

According to some example embodiments described with respect to FIG. 13, unlike some example embodiments described with respect to FIG. 7, a difference lies in that the first color filter CF1, the grid pattern 310, the light blocking pattern SP, and the microlens layer MLL are located shifted from a central portion of the photodiodes PD toward the first direction X.

In some example embodiments, the level by which the first color filter CF1, the grid pattern 310, the light blocking pattern SP, and the microlens layer MLL located in the dummy pixel area (refer to ‘DR’ of FIG. 2) are shifted from the central portion of the photodiodes PD may increase away from the pixel array area (refer to ‘APS’ of FIG. 2), that is, towards an outer portion of the image sensor 100.

Accordingly, the arrangement relationship between the first color filter CF1, the grid pattern 310, the light blocking pattern SP, and the microlens layer MLL and the photodiodes PD in the dummy pixel area DR located at a place adjacent to the pixel array area APS may different from the arrangement relationship between the first color filter CF1, the grid pattern 310, the light blocking pattern SP, and the microlens layer MLL and the photodiodes PD in the dummy pixel area DR located away from the pixel array area APS.

In some example embodiments, at least one of a width of the first color filter CF1 and widths of the microlenses ML of the microlens layer MLL located in the dummy pixel area DR may vary away from the pixel array area APS.

Although FIG. 13 provides illustration and explanation focusing on the first color filter CF1, the description on this may be substantially equally applied to the second color filter CF2 and the third color filter CF3 located on the dummy pixel DPX described above with reference to FIG. 4 and FIG. 5.

As shown in FIG. 13, the light transmitting layer 30 and the photoelectric conversion layer 10 located on the dummy pixels DPX may be located to be shifted. This is for compensation such that, since the light is incident with an oblique angle in the dummy pixel area (refer to ‘DR’ of FIG. 2) located on the outer boundary of the substrate 400, the light incident with the oblique angle may be located at a center of each dummy pixel DPX.

In more detail, referring to FIG. 13, a center of the grid pattern 310 located on the dummy pixels DPX may be located shifted toward the first direction X to be offset from a center of the pixel separation pattern 450. That is, the grid pattern 310 may be located not to overlap with the pixel separation pattern 450 in the third direction Z, which is the vertical direction. However, arrangement relationship between the grid pattern 310 and the pixel separation pattern 450 is not limited thereto, and may be changed in various ways. For example, a portion of the grid pattern 310 located shifted in the first direction X may be located to overlap with a portion of the pixel separation pattern 450 in the third direction Z, which is the vertical direction.

Each of a center of the first color filter CF1 and a center of the light blocking pattern SP located on the dummy pixels DPX may be located shifted toward the first direction X to be offset from a center of the photodiodes PD.

Accordingly, in some example embodiments, a partial region of the light blocking pattern SP may overlap with the photodiode PD in the third direction Z that is the vertical direction, and a remaining region may overlap with the pixel separation pattern 450 in the third direction Z, which is the vertical direction.

In the dummy pixel area DR, a center of the microlenses ML of the microlens layer MLL may be located shifted toward the first direction X to be offset from the center of the first color filter CF1, and a center of the flat portion MLP of the microlens layer MLL may be located shifted toward the first direction X to be offset from the center of the light blocking pattern SP. That is, a portion having a greatest thickness of the microlens ML may be located to be offset from the center of the first color filter CF1.

Accordingly, each of the center of the microlenses ML of the microlens layer MLL and the center of the flat portion MLP may be located to be offset from the center of the photodiodes PD.

In some example embodiments, the microlenses ML and the flat portion MLP of the microlens layer MLL may be further shifted toward the first direction X than the grid pattern 310, the light blocking pattern SP, and the first color filter CF1. However, arrangement relationship of the microlens layer MLL, the grid pattern 310, the light blocking pattern SP, and the first color filter CF1 is not limited thereto, and may be appropriately shifted according to a location of the dummy pixel DPX.

A partial region of the microlenses ML of the microlens layer MLL may overlap with the first color filter CF1, and a remaining region may overlap with the light blocking pattern SP. A partial region of the flat portion MLP of the microlens layer MLL may overlap with the first color filter CF1, and a remaining region may overlap with the light blocking pattern SP.

Each of the flat portion MLP and the microlenses ML of the microlens layer MLL may overlap with the photodiodes PD.

In some example embodiments, overlapping of the photodiode PD, the first color filter CF1, and the microlens layer MLL described above may be a meaning including not only the overlapping relationship along the third direction Z, which is the vertical direction but also the overlapping relationship according to the moving direction of the light incident on the photodiodes PD. That is, the photodiode PD, the first color filter CF1, and the microlenses ML of the microlens layer MLL may be located to overlap with the light incident on the photodiode PD from the outside along the path direction. For example, as the center of the photodiode PD, the center of the first color filter CF1, and the center of the microlenses ML are located to be offset to each other, the center of the photodiode PD, the center of the first color filter CF1, and the center of the microlenses ML may be located on an extension line of the path of light incident on the photodiode PD.

Although not shown in FIG. 13, in an outer portion of the pixel array area APS located to be adjacent to the dummy pixel area DR also, substantially the same as the dummy pixel area DR, the light transmitting layer 30 and the photoelectric conversion layer 10 may be located to be shifted. However, a shift level of the light transmitting layer 30 and the photoelectric conversion layer 10 in the pixel array area APS may be different from a shift level of the light transmitting layer 30 and the photoelectric conversion layer 10 in the dummy pixel area DR. The shift level of the light transmitting layer 30 and the photoelectric conversion layer 10 may increase from a central portion of the pixel array area APS to the outer portion.

Accordingly, in the same way as the dummy pixel area DR, the compensation may be made such that the light incident from the outer portion of the pixel array area APS at the oblique angle may be located at each center of the active pixel PX.

According to an image sensor according to some example embodiments described with respect to FIG. 13, substantially the same effect as image sensors according to some example embodiments previously described may be obtained. Furthermore, the image sensor according to some example embodiments may locate configurations included in the light transmitting layer 30 to be shifted from the photoelectric conversion layer 10 to perform compensation such that the path of the light incident from the outside may be located at the center of the dummy pixel DPX, and thereby light receiving efficiency may be improved.

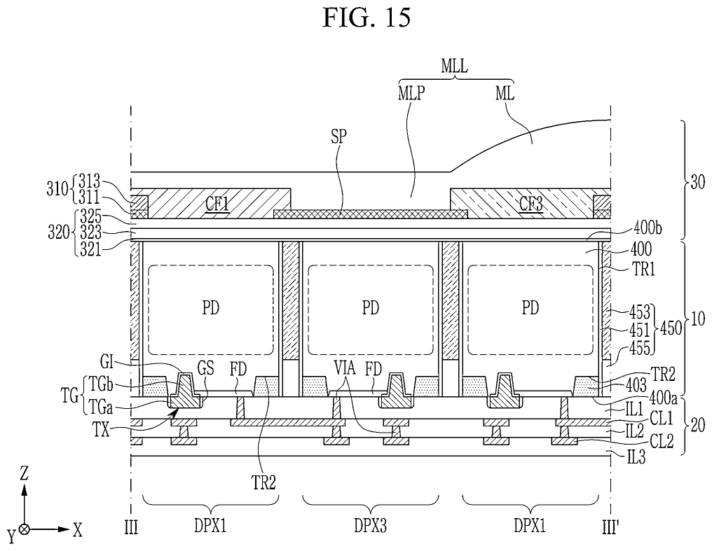

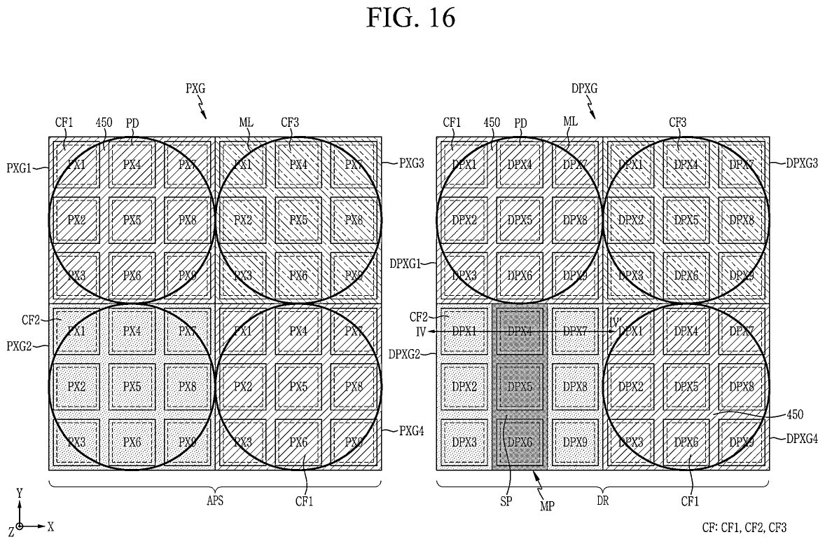

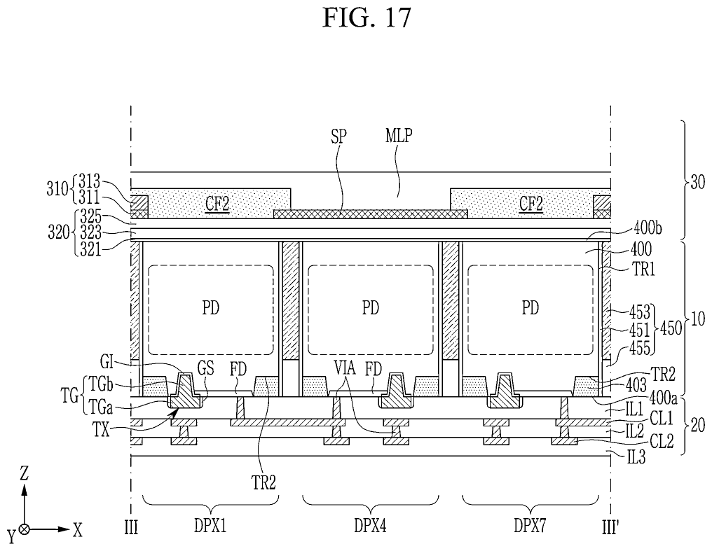

FIG. 14 and FIG. 16 are plan views showing a pixel array area and dummy pixel area of image sensors according to some example embodiments. FIG. 15 is a cross-sectional view taken along line III-III′ of FIG. 14. FIG. 17 is a cross-sectional view taken along line IV-IV′ of FIG. 16.

According to some example embodiments described with respect to FIG. 14 and FIG. 16, unlike some example embodiments described with respect to FIG. 4 and FIG. 5, a difference lies in that the number of the active pixels PX included in the one active pixel group PXG and the number of the dummy pixels DPX included in one dummy pixel group DPXG become different.

According to some example embodiments described with respect to FIG. 14 and FIG. 16, unlike some example embodiments described with respect to FIG. 4 and FIG. 5, a difference lies in that the arrangement form of the color filter CF and the microlens ML become different.

In more detail, referring to FIG. 14 and FIG. 15, in some example embodiments, the active pixel group PXG located in the pixel array area APS may include first to fourth active pixel groups PXG1, PXG2, PXG3, and PXG4. Each of the first to fourth active pixel groups PXG1, PXG2, PXG3, and PXG4 may include first to fourth active pixels PX1, PX2, PX3, and PX4. That is, each of the first to fourth active pixel groups PXG1, PXG2, PXG3, and PXG4 may include the first to fourth active pixels PX1, PX2, PX3, and PX4 arranged in a 2×2 format in a plan view.

In some example embodiments, the color filters CF located in the pixel array area APS may include N×M color filters of an N×M arrangement. The N and the M each may be an integer greater than 1, independently. For example, the N and the M each may be 2, and may have a 2×2 Tetra pattern in a plan view.

For example, the color filter CF may include the first color filter CF1 located to overlap with a first active pixel group PXG1, the second color filter CF2 located to overlap with a second active pixel group PXG2, the third color filter CF3 located to overlap with a third active pixel group PXG3, and the first color filter CF1 located to overlap with a fourth active pixel group PXG4. However, this is merely an example, and the arrangement form of the color filter CF is not limited thereto, and may be changed in various ways.

Each of the first to fourth active pixel groups PXG1, PXG2, PXG3, and PXG4 may overlap with one microlens ML. That is, the one microlens ML may overlap with the first to fourth active pixels PX1, PX2, PX3, and PX4. However, this is merely an example, and the arrangement form of the microlens ML is not limited thereto, and may be changed in various ways.

In some example embodiments, the dummy pixel group DPXG located in the dummy pixel area DR may include first to fourth dummy pixel groups DPXG1, DPXG2, DPXG3, and DPXG4. Each of the first to fourth dummy pixel groups DPXG1, DPXG2, DPXG3, and DPXG4 may include first to fourth dummy pixels DPX1, DPX2, DPX3, and DPX4. That is, each of the first to fourth dummy pixel groups DPXG1, DPXG2, DPXG3, and DPXG4 may include the first to fourth dummy pixels DPX1, DPX2, DPX3, and DPX4 arranged in a 2×2 format in a plan view.

At least a portion of the first to fourth dummy pixels DPX1, DPX2, DPX3, and DPX4 included in each of the first to fourth dummy pixel groups DPXG1, DPXG2, DPXG3, and DPXG4 may overlap with the light blocking pattern SP.

Accordingly, the mark pattern MP configured as the light blocking pattern SP may overlap with at least a portion among the first to fourth dummy pixels DPX1, DPX2, DPX3, and DPX4 included in each of the first to fourth dummy pixel groups DPXG1, DPXG2, DPXG3, and DPXG4.

In some example embodiments, a portion of the color filters CF located in the first to fourth dummy pixel groups DPXG1, DPXG2, DPXG3, and DPXG4 located in the dummy pixel area DR may have an arrangement form different from that of the color filters CF located in the pixel array area APS. That is, a portion of the color filters CF located on the first to fourth dummy pixel groups DPXG1, DPXG2, DPXG3, and DPXG4 may be located not to overlap with the light blocking pattern SP.

For example, the first color filter CF1 may be located on only a portion of the first to fourth dummy pixels DPX1, DPX2, DPX3, and DPX4 included in the first dummy pixel group DPXG1. That is, the first color filter CF1 may be located on a first dummy pixel DPX1 and a second dummy pixel DPX2 that do not overlap with the light blocking pattern SP, and may not be located on a third dummy pixel DPX3 and a fourth dummy pixel DPX4 that overlap with the light blocking pattern SP. For example, a portion of the first color filter CF1 located on the first dummy pixel group DPXG1 may be omitted.

The second color filter CF2 may be located on only a portion of the first to fourth dummy pixels DPX1, DPX2, DPX3, and DPX4 included in the second dummy pixel group DPXG2. That is, the second color filter CF2 may be located on the first dummy pixel DPX1, the second dummy pixel DPX2, and the fourth dummy pixel DPX4 that do not overlap with the light blocking pattern SP, and may not be located on the third dummy pixel DPX3 that overlap with the light blocking pattern SP. For example, a portion of the second color filter CF2 located on the second dummy pixel group DPXG2 may be omitted.

The third color filter CF3 may be located to correspond to the first to fourth dummy pixels DPX1, DPX2, DPX3, and DPX4 included in the third dummy pixel group DPXG3. That is, the third color filter CF3 may be located to overlap with the first to fourth dummy pixels DPX1, DPX2, DPX3, and DPX4 that do not overlap with the light blocking pattern SP. For example, the third color filter CF3 may be located in a 2×2 Tetra pattern in a plan view, on the third dummy pixel group DPXG3.

The first color filter CF1 may be located to correspond to the first to fourth dummy pixels DPX1, DPX2, DPX3, and DPX4 included in the fourth dummy pixel group DPXG4. That is, the first color filter CF1 located on the fourth dummy pixel group DPXG4 may be substantially the same as an arrangement form of the third color filter CF3 in a plan view located on the third dummy pixel group DPXG3.

Unlike from what is shown in FIG. 14, in some example embodiments, the light blocking pattern SP may be located to overlap with at least one of the first to fourth dummy pixel groups DPXG1, DPXG2, DPXG3, and DPXG4 included in the dummy pixel group DPXG.

For example, the first dummy pixel group DPXG1 and the second dummy pixel group DPXG2 may overlap with the light blocking pattern SP, and each of the third dummy pixel group DPXG3 and the fourth dummy pixel group DPXG4 may respectively overlap with the third color filter CF3 and overlap with the first color filter CF1. That is, the light blocking pattern SP may be located to overlap with the first to fourth dummy pixels DPX1, DPX2, DPX3, and DPX4 arranged in a 2×2 format in a plan view in each of the first dummy pixel group DPXG1 and the second dummy pixel group DPXG2.

Accordingly, the mark pattern MP configured as the light blocking pattern SP overlapping with the first dummy pixel group DPXG1 and the second dummy pixel group DPXG2 and extending in the second direction Y may not overlap with the third color filter CF3 and the first color filter CF1 located in each of the third dummy pixel group DPXG3 and the fourth dummy pixel group DPXG4.

A portion of the first to fourth dummy pixel groups DPXG1, DPXG2, DPXG3, and DPXG4 included in the dummy pixel group DPXG may overlap with the one microlens ML. The microlens ML may be located in a pixel group that does not include the light blocking pattern SP among the first to fourth dummy pixel groups DPXG1, DPXG2, DPXG3, and DPXG4. For example, the microlens ML may not located in a pixel group that includes the light blocking pattern SP among the first to fourth dummy pixel groups DPXG1, DPXG2, DPXG3, and DPXG4.

For example, as shown in FIG. 14, as the third dummy pixel DPX3 and the fourth dummy pixel DPX4 among the first to fourth dummy pixels DPX1, DPX2, DPX3, and DPX4 included in the first dummy pixel group DPXG1 overlap with the light blocking pattern SP, the microlenses ML of the microlens layer MLL may not be located on the first dummy pixel group DPXG1.

Although not shown in FIG. 14, the flat portion (refer to ‘MLP’ of FIG. 15) of the microlens layer (refer to ‘MLL’ of FIG. 15) may be entirely located on the first dummy pixel group DPXG1, and may overlap with the first to fourth dummy pixels DPX1, DPX2, DPX3, and DPX4 included in the first dummy pixel group DPXG1. For example, as shown in FIG. 15, the flat portion MLP of the microlens layer MLL may be located to overlap with the first color filter CF1 and the light blocking pattern SP in the third direction Z, which is the vertical direction.

As the third dummy pixel DPX3 among the first to fourth dummy pixels DPX1, DPX2, DPX3, and DPX4 included in the second dummy pixel group DPXG2 overlap with the light blocking pattern SP, the microlens ML may not be located on the second dummy pixel group DPXG2.

Although not shown in FIG. 14, the flat portion MLP of the microlens layer MLL may be entirely located on the second dummy pixel group DPXG2, and may overlap with the first to fourth dummy pixels DPX1, DPX2, DPX3, and DPX4 included in the second dummy pixel group DPXG2.

As shown in FIG. 14 and FIG. 15, since each of the first to fourth dummy pixels DPX1, DPX2, DPX3, and DPX4 included each of the third dummy pixel group DPXG3 and the fourth dummy pixel group DPXG4 does not overlap with the light blocking pattern SP, the one microlens ML may be located in each of the third dummy pixel group DPXG3 and the fourth dummy pixel group DPXG4. That is, the one microlens ML located in each of the third dummy pixel group DPXG3 and the fourth dummy pixel group DPXG4 may be located to overlap with the first to fourth dummy pixels DPX1, DPX2, DPX3, and DPX4. However, this is merely an example, and the arrangement form of the microlens ML is not limited thereto, and may be changed in various ways.

Referring to FIG. 16 and FIG. 17, in some example embodiments, the active pixel group PXG located in the pixel array area APS may include the first to fourth active pixel groups PXG1, PXG2, PXG3, and PXG4. Each of the first to fourth active pixel groups PXG1, PXG2, PXG3, and PXG4 may include first to ninth active pixels PX1, PX2, PX3, PX4, PX5, PX6, PX7, PX8, and PX9. That is, each of the first to fourth active pixel groups PXG1, PXG2, PXG3, and PXG4 may include the first to ninth active pixels PX1, PX2, PX3, PX4, PX5, PX6, PX7, PX8, and PX9 arranged in a 3×3 format in a plan view.

In some example embodiments, the color filters CF located in the pixel array area APS may include N×M color filters of an N×M arrangement. The N and the M each may be an integer greater than 1, independently. For example, the N and the M each may be 3, and may have 3×3 Nona pattern in a plan view.

That is, the color filter CF may include the first color filter CF1 located to overlap with the first active pixel group PXG1, the second color filter CF2 located to overlap with the second active pixel group PXG2, the third color filter CF3 located to overlap with the third active pixel group PXG3, the first color filter CF1 located to overlap with the fourth active pixel group PXG4. However, this is merely an example, and the arrangement form of the color filter CF is not limited thereto, and may be changed in various ways.

Each of the first to fourth active pixel groups PXG1, PXG2, PXG3, and PXG4 may overlap with the one microlens ML. That is, the one microlens ML may overlap with the first to ninth active pixels PX1, PX2, PX3, PX4, PX5, PX6, PX7, PX8, and PX9. However, this is merely an example, and the arrangement form of the microlens ML is not limited thereto, and may be changed in various ways.

In some example embodiments, the dummy pixel group DPXG located in the dummy pixel area DR may include the first to fourth dummy pixel groups DPXG1, DPXG2, DPXG3, and DPXG4. Each of the first to fourth dummy pixel groups DPXG1, DPXG2, DPXG3, and DPXG4 may include first to ninth dummy pixels DPX1, DPX2, DPX3, DPX4, DPX5, DPX6, DPX7, DPX8, and DPX9. That is, each of the first to fourth dummy pixel groups DPXG1, DPXG2, DPXG3, and DPXG4 may include the first to ninth dummy pixels DPX1, DPX2, DPX3, DPX4, DPX5, DPX6, DPX7, DPX8, and DPX9 arranged in a 3×3 format in a plan view.

At least a portion of the first to ninth dummy pixels DPX1, DPX2, DPX3, DPX4, DPX5, DPX6, DPX7, DPX8, and DPX9 included in each of the first to fourth pixel groups DPXG1, DPXG2, DPXG3, and DPXG4 may overlap with the light blocking pattern SP.

Accordingly, the mark pattern MP configured as the light blocking pattern SP may overlap with at least a portion among the first to ninth dummy pixels DPX1, DPX2, DPX3, DPX4, DPX5, DPX6, DPX7, DPX8, and DPX9 included in each of the first to fourth dummy pixel groups DPXG1, DPXG2, DPXG3, and DPXG4.

In some example embodiments, a portion of the color filters CF located in the first to fourth dummy pixel groups DPXG1, DPXG2, DPXG3, and DPXG4 located in the dummy pixel area DR may have an arrangement form different from that of the color filters CF located in the pixel array area APS. That is, a portion of the color filters CF located on the first to fourth dummy pixel groups DPXG1, DPXG2, DPXG3, and DPXG4 may be located not to overlap with the light blocking pattern SP.

For example, the first color filter CF1 may be located to overlap with the first to ninth dummy pixels DPX1, DPX2, DPX3, DPX4, DPX5, DPX6, DPX7, DPX8, and DPX9 included in the first dummy pixel group DPXG1. That is, the first color filter CF1 located on the first dummy pixel group DPXG1 may be substantially the same as an arrangement form of the first color filter CF1 in a plan view located on the first active pixel group PXG1 in the pixel array area APS.

The second color filter CF2 may be located on only a portion of the first to ninth dummy pixels DPX1, DPX2, DPX3, DPX4, DPX5, DPX6, DPX7, DPX8, and DPX9 included in the second dummy pixel group DPXG2. That is, the second color filter CF2 may be located on the first dummy pixel DPX1, the second dummy pixel DPX2, the third dummy pixel DPX3, the seventh dummy pixel DPX7, the eighth dummy pixel DPX8, and the ninth dummy pixel DPX9 that do not overlap with the light blocking pattern SP, and may not be located on the fourth dummy pixel DPX4, the fifth dummy pixel DPX5, and the sixth dummy pixel DPX6 that overlap with the light blocking pattern SP. For example, a portion of the second color filter CF2 located on the second dummy pixel group DPXG2 may be omitted.

The arrangement form of the third color filter CF3 and the first color filter CF1 located respectively in each of the third dummy pixel group DPXG3 and the fourth dummy pixel group DPXG4 may have substantially the same arrangement form as the first color filter CF1 located on the first dummy pixel group DPXG1. That is, each of the third color filter CF3 and the first color filter CF1 located in each of the third dummy pixel group DPXG3 and the fourth dummy pixel group DPXG4 may be located in a 3×3 Nona pattern in a plan view. However, the arrangement form of the color filter CF is not limited thereto, and may be changed in various ways.

Unlike from what is shown in FIG. 16, in some example embodiments, the light blocking pattern SP may be located to overlap with the at least one of the first to fourth dummy pixel groups DPXG1, DPXG2, DPXG3, and DPXG4 included in the dummy pixel group DPXG.

For example, the first dummy pixel group DPXG1 and the second dummy pixel group DPXG2 may overlap with the light blocking pattern SP, and each of the third dummy pixel group DPXG3 and the fourth dummy pixel group DPXG4 may overlap with the third color filter CF3 and the first color filter CF1. That is, the light blocking pattern SP may be located to overlap with the first to ninth dummy pixels DPX1, DPX2, DPX3, DPX4, DPX5, DPX6, DPX7, DPX8, and DPX9 arranged in a 3×3 format in a plan view in each of the first dummy pixel group DPXG1 and the second dummy pixel group DPXG2.

Accordingly, the mark pattern MP configured as the light blocking pattern SP overlapping with the first dummy pixel group DPXG1 and the second dummy pixel group DPXG2 and extending in the second direction Y may not overlap with the third color filter CF3 and the first color filter CF1 located in each of the third dummy pixel group DPXG3 and the fourth dummy pixel group DPXG4.

A portion of the first to fourth dummy pixel groups DPXG1, DPXG2, DPXG3, and DPXG4 included in the dummy pixel group DPXG may overlap with the one microlens ML.

The microlens ML may be located in a pixel group that does not include the light blocking pattern SP among the first to fourth dummy pixel groups DPXG1, DPXG2, DPXG3, and DPXG4. For example, the microlens ML may not be located in a pixel group that includes the light blocking pattern SP among the first to fourth dummy pixel groups DPXG1, DPXG2, DPXG3, and DPXG4.

For example, as shown in FIG. 16, since each of the first to ninth dummy pixels DPX1, DPX2, DPX3, DPX4, DPX5, DPX6, DPX7, DPX8, and DPX9 included each of the first dummy pixel group DPXG1, the third dummy pixel group DPXG3, and the fourth dummy pixel group DPXG4 do not overlap with the light blocking pattern SP, the one microlens ML may be located in each of the first dummy pixel group DPXG1, the third dummy pixel group DPXG3, and the fourth dummy pixel group DPXG4.

That is, the one microlens ML located in each of the first dummy pixel group DPXG1, the third dummy pixel group DPXG3, and the fourth dummy pixel group DPXG4 may be located to overlap with a plurality of first to ninth dummy pixels DPX1, DPX2, DPX3, DPX4, DPX5, DPX6, DPX7, DPX8, and DPX9.

As shown in FIG. 16, as the fourth dummy pixel DPX4, the fifth dummy pixel DPX5, and the sixth dummy pixel DPX6 among the first to ninth dummy pixels DPX1, DPX2, DPX3, DPX4, DPX5, DPX6, DPX7, DPX8, and DPX9 included in the second dummy pixel group DPXG2 overlap with the light blocking pattern SP, the microlenses ML of the microlens layer MLL may not be located on the second dummy pixel group DPXG2.

Although not shown in FIG. 16, the flat portion (refer to ‘MLP’ of FIG. 17) of the microlens layer (refer to ‘MLL’ of FIG. 17) may be entirely located on the second dummy pixel group DPXG2, and may overlap with the first to ninth dummy pixels DPX1, DPX2, DPX3, DPX4, DPX5, DPX6, DPX7, DPX8, and DPX9 included in the second dummy pixel group DPXG2. For example, as shown in FIG. 17, the flat portion MLP of the microlens layer MLL may be located to overlap with the second color filters CF2 and the light blocking pattern SP in the third direction Z, which is the vertical direction. That is, the flat portion MLP of the microlens layer MLL may entirely cover the second color filters CF2 and the light blocking pattern SP. However, this is merely an example, and the arrangement form of the microlenses ML of the microlens layer MLL and the flat portion MLP is not limited thereto, and may be changed in various ways.

According to image sensors according to some example embodiments described with respect to FIG. 14 to FIG. 17, image sensors according to some example embodiments may also have substantially the same effect as some example embodiments previously described.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While this disclosure has been described in connection with what is presently considered to be some example embodiments, it is to be understood that the disclosure is not limited to the disclosed some example embodiments, but, on the contrary, is intended to cover various modifications and equivalent dispositions included within the spirit and scope of the appended claims.

What is claimed is:

1. An image sensor, comprising:
a substrate comprising a pixel array area and a dummy pixel area surrounding the pixel array area;
a plurality of photodiodes within the substrate;
a pixel separation pattern between the plurality of photodiodes;
a light blocking pattern overlapping at least one of the plurality of photodiodes in the dummy pixel area;
a plurality of color filters on the plurality of photodiodes; and
a microlens layer on the plurality of color filters and the light blocking pattern, the microlens layer comprising a flat portion and a plurality of microlenses,
wherein in the dummy pixel area
the flat portion of the microlens layer overlaps the light blocking pattern, and
the plurality of microlenses of the microlens layer are spaced apart with the flat portion interposed between microlenses of the plurality of microlenses, and the plurality of microlenses are on the plurality of color filters.

2. The image sensor of claim 1, wherein
a central portion of the light blocking pattern does not overlap with the plurality of color filters and the plurality of microlenses; and
an edge portion of the light blocking pattern overlaps with the plurality of color filters and the plurality of microlenses.

3. The image sensor of claim 2, wherein in the dummy pixel area, the plurality of color filters are spaced apart with the light blocking pattern interposed between color filters of the plurality of color filters.

4. The image sensor of claim 3, wherein upper surfaces of the plurality of microlenses are at a level higher than an upper surface of the flat portion.

5. The image sensor of claim 1, further comprising a grid pattern between the plurality of color filters, the grid pattern overlapping the pixel separation pattern,
wherein the grid pattern comprises a first grid pattern, and a second grid pattern on the first grid pattern, and
wherein the light blocking pattern comprises a same material as one of the first grid pattern and the second grid pattern.

6. The image sensor of claim 5, wherein the light blocking pattern comprises a first light blocking pattern comprising a same material as the first grid pattern.

7. The image sensor of claim 6, wherein
the light blocking pattern further comprises a second light blocking pattern on the first light blocking pattern, and
the second light blocking pattern comprises a same material as the second grid pattern.

8. The image sensor of claim 7, wherein a first thickness of the first light blocking pattern and a second thickness of the second light blocking pattern are different.

9. The image sensor of claim 8, wherein
a third thickness of the first grid pattern is a same thickness as the first thickness of the first light blocking pattern, and
a fourth thickness of the second grid pattern is a same thickness as the second thickness of the second light blocking pattern.

10. The image sensor of claim 7, wherein
the first grid pattern and the first light blocking pattern comprise a metal material, and
the second grid pattern and the second light blocking pattern comprise material having lower refractive index than the plurality of color filters.

11. The image sensor of claim 1, wherein
the light blocking pattern comprises at least one first refractive layer and at least one second refractive layer alternately stacked sequentially, and
a first refractive index of the first refractive layer is smaller than a second refractive index of the second refractive layer.

12. The image sensor of claim 1, wherein the light blocking pattern has a line shape or an island shape in plan view.

13. The image sensor of claim 1, wherein in the dummy pixel area
each of centers of the plurality of color filters and a center of the light blocking pattern are located offset from centers of the plurality of photodiodes,
centers of the plurality of microlenses are offset from the centers of the plurality of color filters, and
a center of the flat portion is offset from the center of the light blocking pattern.

14. An image sensor, comprising:
a substrate comprising a pixel array area and a dummy pixel area surrounding the pixel array area;
a plurality of photodiodes within the substrate;
a pixel separation pattern between the plurality of photodiodes;
a light blocking pattern overlapping at least one of the plurality of photodiodes in the dummy pixel area;
a plurality of color filters on the plurality of photodiodes;
a grid pattern between the plurality of color filters, the grid pattern overlapping the pixel separation pattern; and
a microlens layer comprising a flat portion and a plurality of microlenses, the microlens layer being on the plurality of color filters and the light blocking pattern,
wherein in the dummy pixel area
the plurality of color filters cover at least a portion of an upper surface of the light blocking pattern,
the flat portion overlaps the light blocking pattern, and
the plurality of microlenses are spaced apart with the flat portion interposed between microlenses of the plurality of microlenses, and the plurality of microlenses are on the plurality of color filters.

15. The image sensor of claim 14, wherein in the dummy pixel area, the plurality of color filters entirely cover the upper surface of the light blocking pattern.

16. The image sensor of claim 15, wherein in the dummy pixel area, the plurality of color filters comprise:
a first color filter on an edge of the upper surface of the light blocking pattern; and
a second color filter on a central portion of the upper surface of the light blocking pattern,
wherein an upper surface of the second color filter is at a level higher than an upper surface of the first color filter.

17. The image sensor of claim 14, wherein the grid pattern and the light blocking pattern comprise different materials.

18. The image sensor of claim 14, wherein in the dummy pixel area
the substrate comprises a first dummy pixel group and a second dummy pixel group,
each of the first dummy pixel group and the second dummy pixel group comprises a plurality of dummy pixels corresponding to the plurality of photodiodes,
the first dummy pixel group overlaps the light blocking pattern,
the second dummy pixel group does not overlap the light blocking pattern,
the plurality of color filters comprises a first color filter, a second color filter, and a third color filter having different colors, and
each of the first dummy pixel group and the second dummy pixel group overlap a first one among the first color filter, the second color filter, and the third color filter.

19. The image sensor of claim 18, wherein in the dummy pixel area
the flat portion overlaps the first dummy pixel group, and
the plurality of microlenses overlap with the second dummy pixel group.

20. An image sensor, comprising:
a substrate comprising a pixel array area and a dummy pixel area surrounding the pixel array area;
a plurality of photodiodes within the substrate;
a pixel separation pattern between the plurality of photodiodes;
a light blocking pattern overlapping at least one of the plurality of photodiodes in the dummy pixel area;
a plurality of color filters on the plurality of photodiodes and the light blocking pattern;
a grid pattern between the plurality of color filters, the grid pattern overlapping the pixel separation pattern; and
a plurality of microlenses on the plurality of color filters,
wherein in the dummy pixel area
the light blocking pattern is entirely covered by the plurality of color filters, and
the light blocking pattern overlaps the plurality of microlenses.
